(19) United States
(12) Patent Application Publication
(10) Pub. No.: US 2024/0385396 A1
(43) Pub. Date: Nov. 21, 2024

(54) RECEPTION DEVICE, COMMUNICATION DEVICE, AND COMMUNICATION SYSTEM

(71) Applicant: NEC Corporation, Minato-ku, Tokyo (JP)

(72) Inventors: Koya Takata, Tokyo (JP); Hisashi Mizumoto, Tokyo (JP); Fujio Okumura, Kanagawa (JP)

(73) Assignee: NEC Corporation, Minato-ku, Tokyo (JP)

(21) Appl. No.: 18/696,407

(22) PCT Filed: Oct. 29, 2021
(86) PCT No.: PCT/JP2021/040099

§ 371 Date: Mar. 28, 2024

(51) Int. Cl. G02B 6/42; H04B 10/40

(52) U.S. Cl. CPC G02B 6/4214; H04B 10/40

(57) ABSTRACT

Provided is a reception device that includes a ball lens that collects an optical signal propagating through a space, a light guide including a plurality of base-units annularly disposed around the ball lens, the light guide guiding the optical signal collected by the ball lens in a direction substantially perpendicular to an incidence direction of the optical signal, and a plurality of light receiving elements related to the plurality of respective base-units, the light receiving elements receiving the optical signal emitted from the base-units and outputting a signal derived from the received optical signal.

### TECHNICAL FIELD

The present disclosure relates to a reception device or the like that receives an optical signal propagating in a space.

### BACKGROUND ART

In optical spatial communication, the optical signal (hereinafter, also referred to as a spatial optical signal) propagating in space are transmitted and received without using a medium such as an optical fiber. In order to receive a spatial optical signal propagating in a wide space, it is preferable to use a lens having as large a diameter as possible. In the optical spatial communication, a light receiving element having a small electrostatic capacitance is used in order to perform high speed communication. Such a light receiving element has a light receiving unit with a small area. Since the focal distance of the lens is limited, it is difficult to guide a spatial optical signal coming from various directions to a light receiving unit having a small area using a large-diameter lens.

PTL 1 discloses an optical reception device that has little angle dependence with respect to a wide light receiving angle and is intended to enable highly efficient reception. The device of PTL 1 includes a spherical lens, an optical fiber bundle, and at least one light receiving element. The spherical lens collects light incident from a wide angle on one end face of the optical fiber bundle. The optical fiber bundle is a bundle structure in which a plurality of optical fibers is aggregated. One end face of the optical fiber bundle is a face-shaped light incident part. The light incident part is provided at a focal point distribution position of the spherical lens. The at least one light receiving element is provided on the other end face of the optical fiber bundle. The at least one light receiving element receives emitted light emitted from the other end face of the optical fiber bundle.

### CITATION LIST

### Patent Literature

PTL 1: JP 63 095407 A

### SUMMARY OF INVENTION

### Technical Problem

In the method of PTL 1, light collected by a spherical lens is received by an optical fiber bundle including a plurality of optical fibers. The angle at which each optical fiber can collect light is very limited. Therefore, the incident face of each optical fiber is required to be disposed substantially perpendicular to the spherical lens. As a result, one end face of the optical fiber bundle is large relative to the diameter of the spherical lens. For example, even when an optical fiber is not used, when the periphery of the ball lens is surrounded by a band-shaped sensor array, an optical signal coming from an orientation of 360 degrees can be received. However, in such a configuration, the number of light receiving elements is enormous.

An object of the present disclosure is to provide a reception device and the like capable of receiving an optical signal coming from various directions using an appropriate number of light receiving elements.

### Solution to Problem

A reception device according to an aspect of the present disclosure includes a ball lens that collects an optical signal propagating through a space, a light guide including a plurality of base-units annularly disposed around the ball lens, the light guide guiding the optical signal collected by the ball lens in a direction substantially perpendicular to an incidence direction of the optical signal, and a plurality of light receiving elements related to the plurality of respective base-units, the light receiving elements receiving the optical signal emitted from the base-units and outputting a signal derived from the received optical signal.

### Advantageous Effects of Invention

According to the present disclosure, it is possible to provide a reception device and the like capable of receiving the optical signal coming from various directions using an appropriate number of light receiving elements.

### BRIEF DESCRIPTION OF DRAWINGS

FIG. 1 is a conceptual diagram illustrating an example of a configuration of a reception device according to a first example embodiment.

FIG. 2 is a conceptual diagram illustrating an example of a configuration of the reception device according to the first example embodiment.

FIG. 3 is a conceptual diagram for describing an example of light collection by a ball lens of the reception device according to the first example embodiment.

FIG. 4 is a conceptual diagram illustrating an example of a configuration of a base-unit constituting a base-unit of the reception device according to the first example embodiment.

FIG. 5 is a conceptual diagram illustrating an example of a cross section of the base-unit constituting the base-unit of the reception device according to the first example embodiment.

FIG. 6 is a conceptual diagram illustrating an example of reception of a spatial optical signal by the reception device according to the first example embodiment.

FIG. 7 is a conceptual diagram illustrating an example of reception of a spatial optical signal by the reception device according to the first example embodiment.

FIG. 8 is a conceptual diagram illustrating an example of a configuration of a reception device according to a second example embodiment.

FIG. 9 is a conceptual diagram illustrating an example of a configuration of the reception device according to the second example embodiment.

FIG. 10 is a conceptual diagram illustrating an example of a configuration of a base-unit constituting a base-unit of the reception device according to the second example embodiment.

FIG. 11 is a conceptual diagram illustrating an example of a cross section of the base-unit constituting the base-unit of the reception device according to the second example embodiment.

FIG. 12 is a conceptual diagram illustrating an example of a configuration of a reception device according to a third example embodiment.

FIG. 13 is a conceptual diagram illustrating an example of a configuration of the reception device according to the third example embodiment.

FIG. 14 is a conceptual diagram illustrating an example of a cross section of the reception device according to the third example embodiment.

FIG. 15 is a conceptual diagram illustrating an example of reception of an optical signal by the reception device according to the third example embodiment.

FIG. 16 is a conceptual diagram illustrating an example of reception of an optical signal by the reception device according to the third example embodiment.

FIG. 17 is a conceptual diagram illustrating an example of reception of an optical signal in the first modification of the third example embodiment.

FIG. 18 is a conceptual diagram illustrating an example of reception of an optical signal in the first modification of the third example embodiment.

FIG. 19 is a conceptual diagram illustrating an example of reception of an optical signal in the second modification of the third example embodiment.

FIG. 20 is a conceptual diagram illustrating an example of reception of an optical signal in the second modification of the third example embodiment.

FIG. 21 is a conceptual diagram illustrating an example of a configuration of a reception device according to a fourth example embodiment.

FIG. 22 is a conceptual diagram illustrating an example of a configuration of the reception device according to the fourth example embodiment.

FIG. 23 is a conceptual diagram illustrating an example of a configuration of a base-unit constituting a base-unit of the reception device according to the fourth example embodiment.

FIG. 24 is a conceptual diagram illustrating an example of a configuration of the base-unit constituting the base-unit of the reception device according to the fourth example embodiment.

FIG. 25 is a conceptual diagram illustrating an example of a configuration of a reception device according to the third modification of the fourth example embodiment.

FIG. 26 is a conceptual diagram illustrating an example of a configuration of a base-unit constituting a base-unit of the reception device according to the third modification of the fourth example embodiment.

FIG. 27 is a conceptual diagram illustrating an example of a configuration of a reception device according to the fourth modification of the fourth example embodiment.

FIG. 28 is a conceptual diagram illustrating an example of reception of an optical signal in the reception device according to the fourth modification of the fourth example embodiment.

FIG. 29 is a conceptual diagram illustrating an example of a configuration of a reception device according to a fifth example embodiment.

FIG. 30 is a conceptual diagram illustrating an example of a light guide auxiliary device of the reception device according to the fifth example embodiment.

FIG. 31 is a conceptual diagram illustrating another example of a light guide auxiliary device of the reception device according to the fifth example embodiment.

FIG. 32 is a conceptual diagram illustrating another example of a configuration of a reception device according to the fifth modification of the fifth example embodiment.

FIG. 33 is a conceptual diagram illustrating an example of a configuration of a reception device according to a sixth example embodiment.

FIG. 34 is a conceptual diagram illustrating an example of a configuration of a reception circuit included in the reception device according to the sixth example embodiment.

FIG. 35 is a block diagram illustrating an example of a configuration of a communication device according to a seventh example embodiment.

FIG. 36 is a conceptual diagram illustrating an example of a configuration of a transmission device included in the communication device according to the seventh example embodiment.

FIG. 37 is a conceptual diagram illustrating an example of a configuration of the communication device according to the seventh example embodiment.

FIG. 38 is a conceptual diagram for describing an application example of a communication device according to the seventh example embodiment.

FIG. 39 is a conceptual diagram illustrating an example of a configuration of a reception device according to a eighth example embodiment.

FIG. 40 is a block diagram illustrating an example of a hardware configuration that executes processing and control according to each example embodiment.

### EXAMPLE EMBODIMENT

Hereinafter, embodiments of the present invention will be described with reference to the drawings. However, the example embodiments described below have technically preferable limitations for carrying out the present invention, but the scope of the present invention is not limited to the following. In all the drawings used in the following description of the example embodiment, the same reference numerals are given to the same parts unless there is a particular reason. In the following example embodiments, repeated description of similar configurations and operations may be omitted.

In all the drawings used for description of the following example embodiments, the directions of the arrows in the drawings are merely examples, and do not limit the directions of light and signals. A line indicating a trace of light in the drawings is conceptual, and does not accurately indicate an actual traveling direction or state of light. For example, in the drawings, a change in a traveling direction or a state of light due to refraction, reflection, diffusion, or the like at an interface between air and a substance may be omitted, or a pencil of light may be expressed by one line. There is a case where hatching is not applied to the sectional view due to a reason that a light path is illustrated or a configuration is complicated.

### First Example Embodiment

First, a reception device according to a present example embodiment will be described with reference to the drawings. The reception device of the present example embodiment is used for optical spatial communication in which the optical signal (hereinafter, also referred to as a spatial optical signal) propagating in a space are transmitted and received without using a medium such as an optical fiber. The reception device of the present example embodiment may be used for applications other than optical spatial communication as long as the reception device receives light propagating in a space. In the present example embodiment, unless otherwise specified, the spatial optical signal is regarded as parallel light because it comes from a sufficiently distant position. The drawings used in the description of the present example embodiment are conceptual and do not accurately depict an actual structure.

### (Configuration)

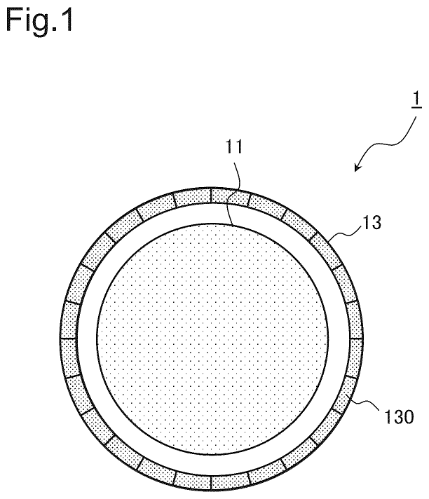

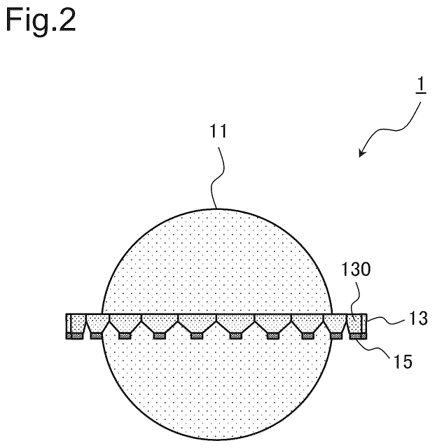

FIGS. 1 to 3 are conceptual diagrams illustrating an example of a configuration of a reception device 1 according to the present example embodiment. The reception device 1 includes a ball lens 11, a light guide 13, and a plurality of light receiving elements 15. FIG. 1 is a plan view of the reception device 1 when viewed from above. FIG. 2 is a side view of the reception device 1 when viewed in the lateral direction. A positional relationship between the ball lens 11 and the light guide 13 is fixed by a support (not illustrated). In the present example embodiment, the support for fixing the light guide 13 to the ball lens 11 is omitted. The ball lens 11 is a spherical lens. The ball lens 11 is an optical element that collects a spatial optical signal coming from the outside. The ball lens 11 has a spherical shape when viewed from an any angle. The ball lens 11 collects the incident spatial optical signal. Light (also referred to as an optical signal) derived from the spatial optical signal collected by the ball lens 11 is collected toward the condensing region. Since the ball lens 11 has a spherical shape, the ball lens collects a spatial optical signal coming from an any direction. That is, the ball lens 11 exhibits similar light condensing performance for a spatial optical signal coming from an any direction.

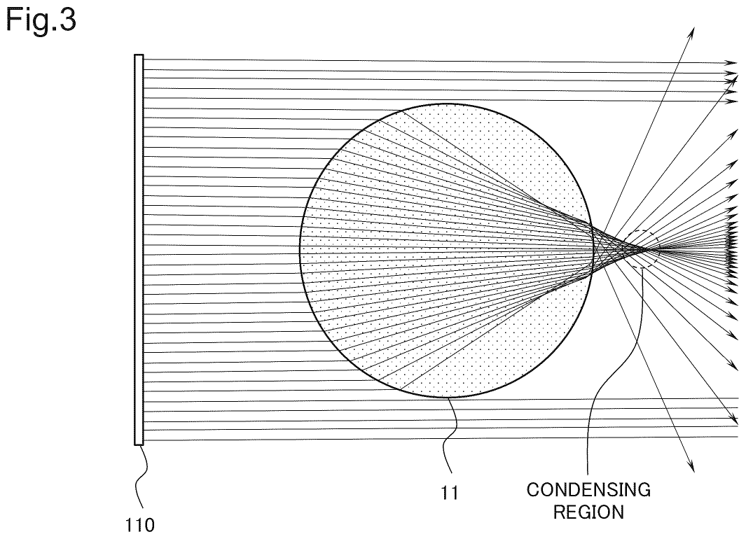

FIG. 3 is a conceptual diagram illustrating an example of a trajectory of light collected by the ball lens 11. The example of FIG. 3 illustrates a state in which light radiated from a light source 110 that emits parallel light toward the ball lens 11 is refracted by the ball lens 11. The light incident on the ball lens 11 is refracted when entering the ball lens 11. The light traveling inside the ball lens 11 is refracted again when being emitted to the outside of the ball lens 11. Most of the light emitted from the ball lens 11 is collected in the condensing region. On the other hand, the light incident on the periphery of the ball lens 11 is emitted in a direction deviated from the condensing region when being emitted from the ball lens 11.

For example, the ball lens 11 can be made of a material such as glass, crystal, or resin. In the case of receiving a spatial optical signal in the visible region, a material such as glass, crystal, or resin that transmits/refracts light in the visible region can be applied to the ball lens 11. For example, optical glass such as crown glass or flint glass can be applied to the ball lens 11. For example, crown glass such as Boron Kron (BK) can be applied to the ball lens 11. For example, flint glass such as Lanthanum Schwerflint (LaSF) can be applied to the ball lens 11. For example, quartz glass can be applied to the ball lens 11. For example, crystal such as sapphire can be applied to the ball lens 11. For example, transparent resin such as acrylic can be applied to the ball lens 11. In a case where the spatial optical signal is light in a near-infrared region (hereinafter, also referred to as near infrared rays), a material that transmits near-infrared rays is used for the ball lens 11. For example, in a case of receiving a spatial optical signal in a near-infrared region of about 1.5 micrometers (μm), a material such as silicon can be applied to the ball lens 11 in addition to glass, crystal, resin, and the like. In a case where the spatial optical signal is light in an infrared region (hereinafter, also referred to as infrared rays), a material that transmits infrared rays is used for the ball lens 11. For example, in a case where the spatial optical signal is an infrared ray, silicon, germanium, or a chalcogenide material can be applied to the ball lens 11. The material of the ball lens 11 is not limited as long as light in the wavelength region of the spatial optical signal can be transmitted/refracted. The material of the ball lens 11 may be appropriately selected according to the required refractive index and use.

The light guide 13 is disposed in the condensing region of the ball lens 11 in such a way as to surround the periphery of the ball lens 11. The light guide 13 includes a plurality of base-units 130. The base-unit 130 has an incident face facing the ball lens 11 and an emission face facing the light receiving unit of the light receiving element 15. The incident face is provided on part of the side face of the base-unit 130. An emission face (also referred to as an emission end) is provided on an end face of the base-unit 130. The incident face and the emission face are formed on faces orthogonal to each other.

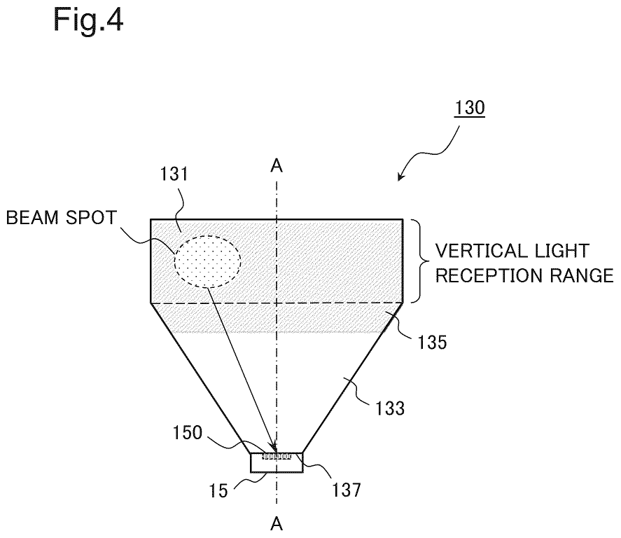

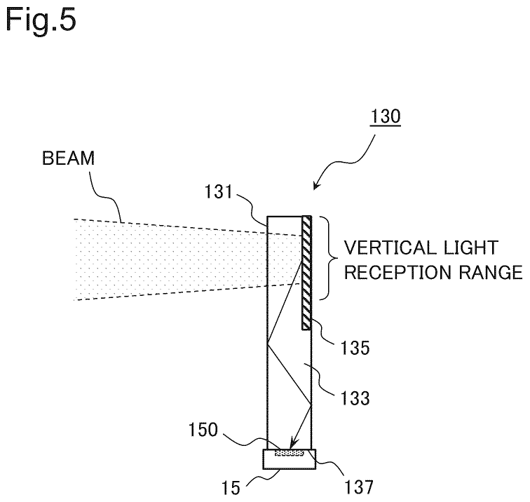

FIGS. 4 to 5 are conceptual diagrams for describing an example of the base-unit 130 constituting the light guide 13. FIG. 4 is a side view of the base-unit 130 when viewed from the side of the ball lens 11. FIG. 5 is a sectional view of the base-unit taken along line A-A in FIG. 4. FIGS. 4 to 5 illustrate an example of the beam spot of the optical signal collected by the ball lens 11 and the path of the optical signal traveling inside the base-unit 130.

The base-unit 130 includes a light guide body 133 and a diffraction element 135. The light guide body 133 is a main body of the base-unit 130. FIG. 4 illustrates the diffraction element 135 disposed on the second face that is seen through the light guide body 133 from the first face.

The light guide body 133 has a first face facing the ball lens 11 and a second face facing the first face. The light guide body 133 has an incident face 131 and an emission face 137. The incident face 131 is provided on part of the first face of the light guide body 133. The emission face 137 is provided on part of the side face of the light guide body 133. The incident face 131 and the emission face 137 are formed on faces orthogonal to each other.

The light guide body 133 has a shape narrowed from a portion where the incident face 131 is provided to a portion where the emission face 137 is provided. In the case of the example of FIG. 4, a portion of the light reception range (vertical light reception range) in which the incident face 131 is provided is rectangular. A portion where the emission face 137 is provided is a trapezoid that is tapered from one side of the rectangle of the vertical light reception range toward a light receiving unit 150 of the light receiving element 15. The shape of the base-unit 130 is not limited to the shape in FIG. 4. For example, the base-unit 130 may be a teardrop type tapered from the vertical light reception range toward the light receiving unit 150. For example, the vertical light reception range of the base-unit 130 may have a shape other than a rectangle.

The light guide body 133 guides the optical signal entering of the light guide body 133 from the vertical light reception range of the first face toward the emission face 137. The signal light entering the light guide body 133 is reflected by the first face and the second face of the light guide body 133 and guided to the light receiving unit 150 of the light receiving element 15. The light guide body 133 is made of a material that transmits a signal light. For example, the light guide body 133 can be made of a material such as glass or plastic. Note that the material of the light guide body 133 is not limited as long as it transmits the signal light.

The diffraction element 135 is an element that guides the optical signal incident on the incident face 131 toward the light receiving unit 150 of the light receiving element 15. The diffraction element 135 is a type of light traveling direction changing element. The diffraction element 135 has a diffraction face that diffracts the optical signal incident on the incident face 131 toward the emission face 137. The diffraction element 135 is disposed on the second face facing the first face on which the incident face 131 of the light guide body 133 is formed. For example, the diffraction element 135 is provided inside the light guide body 133. For example, the diffraction element 135 is disposed with the diffraction face facing the incident face 131 of the light guide body 133. The diffraction element 135 diffracts the optical signal entering the light guide body 133 from the incident face 131 toward the emission face 137 on which the light receiving element 15 is disposed.

For example, the diffraction element 135 includes a reflection type diffraction grating having a structure in which a plurality of gratings having a height in the order of micrometers is disposed. For example, the diffraction element 135 is configured by changing the grating interval in such a way that the total reflection condition is satisfied. For example, the diffraction element 135 diffracts the light in such a way that the total reflection condition is satisfied in such a way that the optical signal incident on the incident face 131 of the light guide body 133 travels toward the emission face 137. For example, the diffraction element 135 can be achieved by a blazed diffraction grating or a holographic diffraction grating.

Each of the plurality of light receiving elements 15 is disposed on the emission face 137 of the light guide 13, the plurality of light receiving elements being in association with the plurality of respective base-units 130 constituting the light guide 13. The light receiving element 15 includes the light receiving unit 150 that receives an optical signal derived from a spatial optical signal to be received. Each light receiving element 15 is disposed with the light receiving unit 150 facing the emission face 137 of the light guide body 133 of the base-unit 130. The traveling direction of the optical signal collected by the ball lens 11 is changed by the light guide 13, and the optical signal is received by the light receiving unit 150 of the light receiving element 15. The light receiving face of each light receiving element 15 includes a region where the light receiving unit 150 is located (also referred to as a light receiving region) and a region where the light receiving unit 150 is not located (also referred to as a dead region).

The light receiving element 15 receives light in a wavelength region of the spatial optical signal to be received. For example, the light receiving element 15 has sensitivity to light in the visible region. For example, the light receiving element 15 has sensitivity to light in an infrared region. The light receiving element 15 is sensitive to light having a wavelength in a 1.5 μm (micrometer) band, for example. The wavelength band of light to which the light receiving element 15 has sensitivity is not limited to the 1.5 μm band. The wavelength band of the light received by the light receiving element 15 can be set to any value in accordance with the wavelength of the spatial optical signal transmitted from the transmission device (not illustrated). The wavelength band of the light received by the light receiving element 15 may be set to, for example, a 0.8 μm band, a 1.55 μm band, or a 2.2 μm band. The wavelength band of the light received by the light receiving element 15 may be, for example, a band of 0.8 to 1 μm. A shorter wavelength band is advantageous for optical spatial communication during rainfall because absorption by moisture in the atmosphere is small. When the light receiving element 15 is saturated with intense sunlight, the light receiving element cannot read the optical signal derived from the spatial optical signal. Therefore, a color filter that selectively passes the light of the wavelength band of the spatial optical signal may be installed before the light receiving element 15.

For example, the light receiving element 15 can be achieved by an element such as a photodiode or a phototransistor. For example, the light receiving element 15 is achieved by an avalanche photodiode. The light receiving element 15 achieved by the avalanche photodiode can support high speed communication. The light receiving element 15 may be achieved by an element other than a photodiode, a phototransistor, or an avalanche photodiode as long as an optical signal can be converted into an electric signal. In order to improve the communication speed, the light receiving unit 150 of the light receiving element 15 is preferably as small as possible. For example, the light receiving unit 150 of the light receiving element 15 has a square light receiving face having a side of about 5 mm (mm). For example, the light receiving unit 150 of the light receiving element 15 has a circular light receiving face having a diameter of about 0.1 to 0.3 mm. The size and shape of the light receiving unit 150 of the light receiving element 15 may be selected according to the wavelength band, the communication speed, and the like of the spatial optical signal.

The light receiving element 15 converts the received optical signal into an electric signal. Light receiving element 15 outputs the converted electric signal to a reception circuit (not illustrated). A configuration including the reception circuit will be described later.

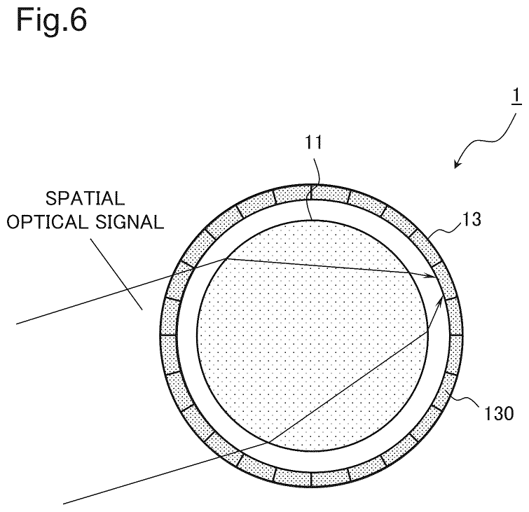

FIG. 6 is a conceptual diagram illustrating an example in which the reception device 1 receives a spatial optical signal. FIG. 6 is a plan view of the reception device 1 when viewed from above. Since the ball lens 11 is a sphere, the reception device 1 can uniformly receive the spatial optical signal coming from any direction as long as the spatial optical signal is within a range where the light can be received by the light guide 13. For example, in a case where the plane formed by the light guide 13 is set to be parallel to the horizontal plane, the reception device 1 easily receives the spatial optical signal coming in the horizontal direction from the same level of height. For example, in a case where the plane formed by the light guide 13 is set perpendicular to the horizontal plane, the reception device 1 similarly easily receives the spatial optical signal coming from an any height.

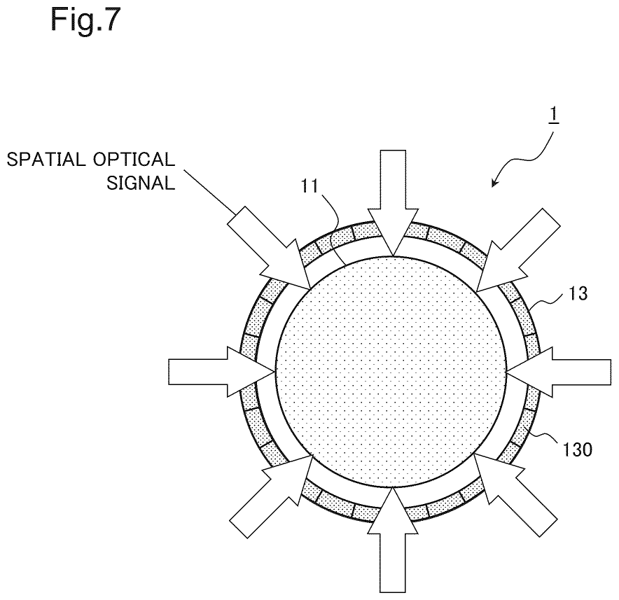

FIG. 7 is a conceptual diagram for describing a light reception range of a spatial optical signal that can be received by the reception device 1. FIG. 7 is a plan view of the reception device 1 when viewed from above. Part of the spatial optical signal coming toward the ball lens 11 is blocked by the light guide 13 and the light receiving element 15, but most of the spatial optical signal is collected by the ball lens 11 and received by the light receiving element 15 via the light guide 13. As illustrated in FIG. 7, the reception device 1 can receive a spatial optical signal coming from a direction of 360 degrees in a plane parallel to a plane including a circle formed by the light guide 13.

As described above, the reception device of the present example embodiment includes the ball lens, the light guide, and the plurality of light receiving elements. The ball lens collects the optical signal propagating in the space. The light guide includes a plurality of base-units annularly disposed around the ball lens. The base-unit includes a light guide body and a light traveling direction changing element. The light guide body includes a first face including an incident face on which the optical signal collected by the ball lens is incident, a second face facing the first face, and an emission end from which the optical signal incident on the incident face is emitted. The light traveling direction changing element is disposed at a position facing the incident face of the second face. The light traveling direction changing element changes the traveling direction of the optical signal incident on the incident face toward the emission end. The light traveling direction changing element is a diffraction element that diffracts the optical signal incident on the incident face toward the emission end. The light guide guides the optical signal collected by the ball lens in a direction substantially perpendicular to the incidence direction of the optical signal. The base-unit is disposed to guide, in a direction perpendicular to a plane formed by the array of the plurality of base-units, the optical signal incident on the incident face. The plurality of light receiving elements is associated with the plurality of respective base-units. The light receiving element receives an optical signal emitted from the base-unit. The light receiving element is disposed with a light receiving unit that receives light in a wavelength region of an optical signal facing an emission end of the base-unit. The light receiving element outputs a signal derived from the received optical signal.

In the reception device of the present example embodiment, the diffraction element included in any of the plurality of base-units constituting the light guide guides the optical signal coming from various directions toward the light receiving element associated with the base-unit. According to the reception device of the present example embodiment, since the optical signal coming from various directions can be collectively received by each base-unit constituting the light guide, the number of light receiving elements can be reduced. Therefore, according to the reception device of the present example embodiment, the optical signal coming from various directions can be received using an appropriate number of light receiving elements.

### Second Example Embodiment

Next, a reception device according to a second example embodiment will be described with reference to the drawings. The reception device of the present example embodiment is different from that of the first example embodiment in the configuration of the light guide. The drawings used in the description of the present example embodiment are conceptual and do not accurately depict an actual structure.

### (Configuration)

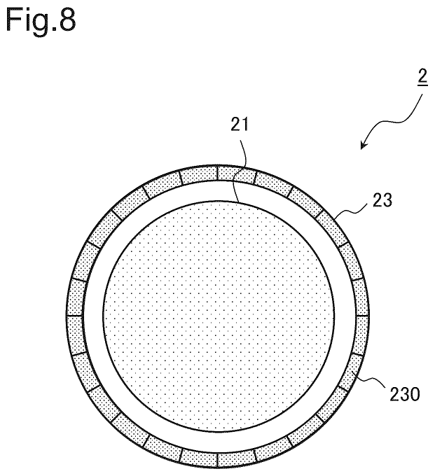

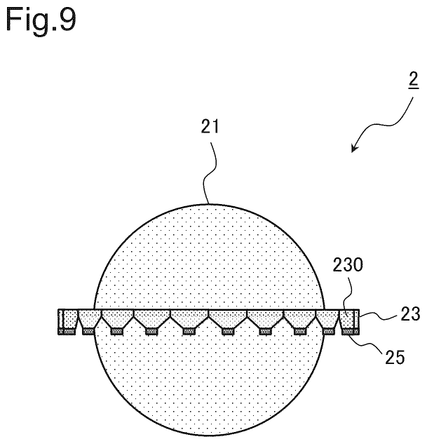

FIGS. 8 to 9 are conceptual diagrams illustrating an example of a configuration of a reception device 2 according to the present example embodiment. The reception device 2 includes a ball lens 21, a light guide 23, and a plurality of light receiving elements 25. FIG. 8 is a plan view of the reception device 2 when viewed from above. FIG. 9 is a side view of the reception device 2 when viewed in the lateral direction. A positional relationship between the ball lens 21 and the light guide 23 is fixed by a support (not illustrated). In the present example embodiment, the support for fixing the light guide 23 to the ball lens 21 is omitted.

The ball lens 21 has a configuration similar to that of the ball lens 11 of the first example embodiment. The ball lens 21 collects a spatial optical signal coming from the outside on a condensing region of the ball lens 21.

The light guide 23 is disposed in the condensing region of the ball lens 21 in such a way as to surround the periphery of the ball lens 21. The light guide 23 includes a plurality of base-units 230. The base-unit 230 has an incident face facing the ball lens 21 and an emission face (also referred to as an emission end) facing the light receiving unit of the light receiving element 25. The incident face is provided on part of the side face of the base-unit 230. The emission face is provided on an end face of the base-unit 230. The incident face and the emission face are formed on faces orthogonal to each other.

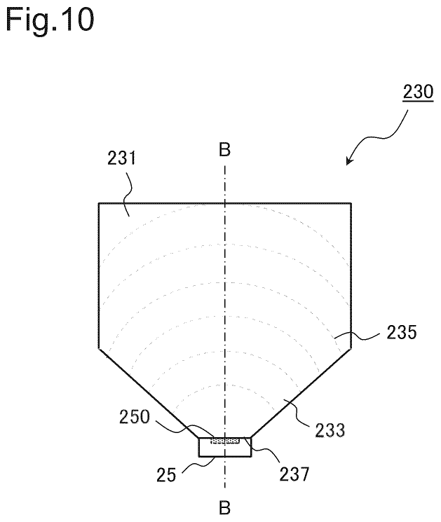

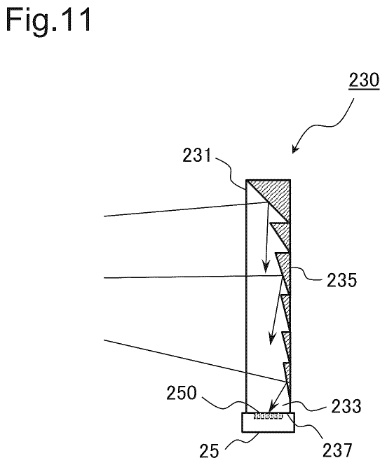

FIGS. 10 to 11 are conceptual diagrams for describing an example of the base-unit 230 constituting the light guide 23. FIG. 10 is a side view of the base-unit 230 when viewed from the side of the ball lens 21. FIG. 11 is a sectional view of the base-unit 230 taken along line B-B in FIG. 10. FIG. 11 illustrates an example of a path of an optical signal traveling inside the base-unit 230.

The base-unit 230 includes a light guide body 233 and a multi-mirror 235. The light guide body 233 is a main body of the base-unit 230. FIG. 10 illustrates the multi-mirror 235 disposed on the second face that is seen through the light guide body 233 from the first face.

The light guide body 233 has a configuration similar to that of the light guide body 133 of the first example embodiment. The light guide body 233 has a first face facing the ball lens 21 and a second face facing the first face. The light guide body 233 has an incident face 231 and an emission face 237. The incident face 231 is provided on part of the first face of the light guide body 233. The emission face 237 is provided on part of the side face of the light guide body 233. The incident face 231 and the emission face 237 are formed on faces orthogonal to each other.

The light guide body 233 guides the optical signal entering the light guide body 233 from the incident face 231 of the first face toward the emission face 237. The signal light entering the light guide body 233 is reflected by the first face and the second face of the light guide body 233 and guided to a light receiving unit 250 of the light receiving element 25.

The multi-mirror 235 is a structure that guides the optical signal incident on the incident face 231 toward the light receiving unit 250 of the light receiving element 25. The multi-mirror 235 is a type of light traveling direction changing element. The multi-mirror 235 has a plurality of reflection faces that reflect the optical signal incident on the incident face 231 toward the emission face 237. The multi-mirror 235 has a plurality of arcuate reflection faces having a center of curvature in the direction of the emission face 237. The shape of the reflection face of the multi-mirror 235 may not be an arc shape but a curved shape such as a parabola, a hyperbola, or an elliptic curve. For example, the multi-mirror 235 is disposed with the reflection face facing the second face facing the first face in which the incident face 231 of the light guide body 233 is formed. The multi-mirror 235 diffracts the optical signal entering the light guide body 233 from the incident face 231 toward the emission face 237 on which the light receiving element 25 is disposed.

As illustrated in FIG. 11, the reflection face of the multi-mirror 235 has a right triangular shape. A reflection face is formed on an inclined face of the reflection face (right triangle) of the multi-mirror 235. The inclined face forming the reflection face of the multi-mirror 235 is set in such a way that the optical signal incident on the incident face 231 faces the emission face 237. The cross section of the reflection face of the multi-mirror 235 may be formed in a curved shape instead of a linear shape. The plurality of reflection faces constituting the multi-mirror 235 is formed in such a way that the height of the vertex on the first face side gradually decreases from the incident face 231 toward the emission face 237. The optical signal reflected by the plurality of reflection faces constituting the multi-mirror 235 travels toward the emission face 237 of the light guide body 233.

For example, the scraped face is formed by scraping the second face of the light guide body 233, and the reflection layer is provided on the scraped face, whereby the multi-mirror 235 can be formed. For example, the reflection layer can be formed by depositing a material having high reflectance such as metal on the scraped face of the light guide body 233. For example, the reflection layer can be formed by depositing metal on the scraped face of the light guide body 233. For example, the multi-mirror 235 may be formed by processing the second face of the light guide body 233 by etching or the like. For example, the multi-mirror 235 may be formed on the second face of the light guide body 233 formed by injection molding, a three-dimensional printer, or the like.

The light receiving element 25 has a configuration similar to that of the light receiving element 15 of the first example embodiment. Each of the plurality of light receiving elements 25 is disposed on the emission face 237 of the light guide 23, the plurality of light receiving elements being in association with the plurality of respective base-units 230 constituting the light guide 23. The light receiving element 25 includes a light receiving unit 250 that receives an optical signal derived from a spatial optical signal to be received. Each light receiving element 25 is disposed with the light receiving unit 250 facing the emission face 237 of the light guide body 233 of the base-unit 230. The traveling direction of the optical signal collected by the ball lens 21 is changed by the light guide 23, and the optical signal is received by the light receiving unit 250 of the light receiving element 25.

The light receiving element 25 converts the received optical signal into an electric signal. Light receiving element 25 outputs the converted electric signal to a reception circuit (not illustrated). A configuration including the reception circuit will be described later.

As described above, the reception device of the present example embodiment includes the ball lens, the light guide, and the plurality of light receiving elements. The ball lens collects the optical signal propagating in the space. The light guide includes a plurality of base-units annularly disposed around the ball lens. The base-unit includes a light guide body and a light traveling direction changing element. The light guide body includes a first face including an incident face on which the optical signal collected by the ball lens is incident, a second face facing the first face, and an emission end from which the optical signal incident on the incident face is emitted. The light traveling direction changing element is disposed at a position facing the incident face of the second face. The light traveling direction changing element changes the traveling direction of the optical signal incident on the incident face toward the emission end. The light traveling direction changing element is a multi-mirror in which a plurality of reflection faces that reflect the optical signal incident on the incident face toward the emission end is combined. The light guide guides the optical signal collected by the ball lens in a direction substantially perpendicular to the incidence direction of the optical signal. The base-unit is disposed to guide, in a direction perpendicular to a plane formed by the array of the plurality of base-units, the optical signal incident on the incident face. The plurality of light receiving elements is associated with the plurality of respective base-units. The light receiving element receives an optical signal emitted from the base-unit. The light receiving element is disposed with a light receiving unit that receives light in a wavelength region of an optical signal facing an emission end of the base-unit. The light receiving element outputs a signal derived from the received optical signal.

In the reception device of the present example embodiment, the multi-mirror included in the base-unit constituting the light guide guides the optical signal coming from various directions toward the light receiving element associated with the base-unit. According to the reception device of the present example embodiment, since the optical signal coming from various directions can be collectively received by each base-unit constituting the light guide, the number of light receiving elements can be reduced. Therefore, according to the reception device of the present example embodiment, the optical signal coming from various directions can be received using an appropriate number of light receiving elements.

### Third Example Embodiment

Next, a reception device according to a third example embodiment will be described with reference to the drawings. The reception device of the present example embodiment is different from the first to second example embodiments in the configuration of the light guide part. The drawings used in the description of the present example embodiment are conceptual and do not accurately depict an actual structure.

### (Configuration)

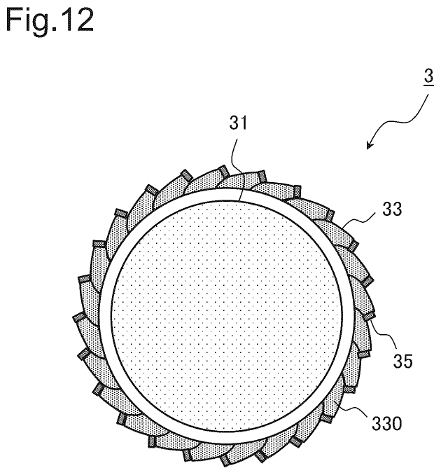

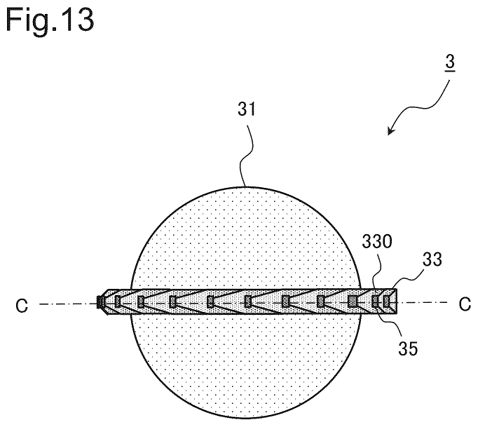

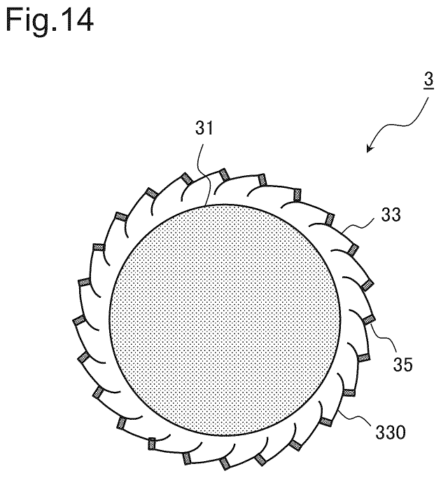

FIGS. 12 to 14 are conceptual diagrams illustrating an example of a configuration of a reception device 3 according to the present example embodiment. The reception device 3 includes a ball lens 31, a light guide 33, and a plurality of light receiving elements 35. FIG. 12 is a plan view of the reception device 3 when viewed from above. FIG. 13 is a side view of the reception device 3 when viewed in the lateral direction. FIG. 14 is a sectional view of the reception device 3 taken along line C-C in FIG. 13. A positional relationship between the ball lens 31 and the light guide 33 is fixed by a support (not illustrated). In the present example embodiment, the support for fixing the light guide 33 to the ball lens 31 is omitted.

The ball lens 31 has a configuration similar to that of the ball lens 11 of the first example embodiment. The ball lens 31 collects a spatial optical signal coming from the outside on a condensing region of the ball lens 31.

The light guide 33 is disposed in the condensing region of the ball lens 31 in such a way as to surround the periphery of the ball lens 31. The light guide 33 includes a plurality of base-units 330. The base-unit 330 has a curved shape in which a concave first face (also referred to as a concave curved face) and a convex second face (also referred to as a convex curved face) face each other like the distal end portion of the spoon. Both faces of the base-unit 330 are reflection faces that reflect the optical signal. The plurality of base-units 330 is disposed with the concave first face facing the ball lens 31. One end of the first face of the base-unit 330 functions as an incident face, and the other end of the first face functions as a light guide part. The base-unit 330 is disposed with one end and the other end of the first face being in accordance with the circumferential direction of the ball lens 31. One end (incident face) of the first face of the base-unit 330 faces the ball lens 31. The other end side (light guide part) of the first face of the base-unit 330 is disposed opposite to the second face of the adjacent base-unit 330. The light receiving element 35 is disposed at the other end of the first face of the base-unit 330. The light receiving element 35 is disposed in such a way that the light receiving face is substantially perpendicular to the first face at a terminal portion of the other end of the first face. The plurality of base-units 330 surrounds the ball lens 31 while each base-unit overlapping the adjacent base-unit 330 like scales of fish.

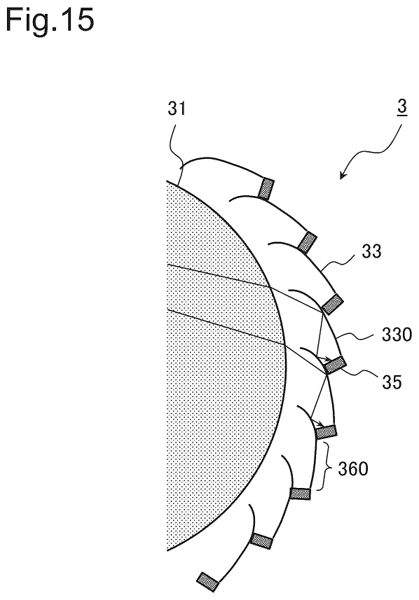

FIG. 15 is an enlarged view of part of the sectional view of FIG. 14. FIG. 15 illustrates an example of a path of the optical signal collected by the ball lens 31. The optical signal collected by the ball lens 31 is incident on the incident face of the first face of the base-unit 330. The optical signal incident on the incident face of the base-unit 330 is reflected between the convex face of the adjacent base-unit 330 and the reflection face of the light guide part of the base-unit 330, and travels toward the light receiving unit 350 of the light receiving element 35.

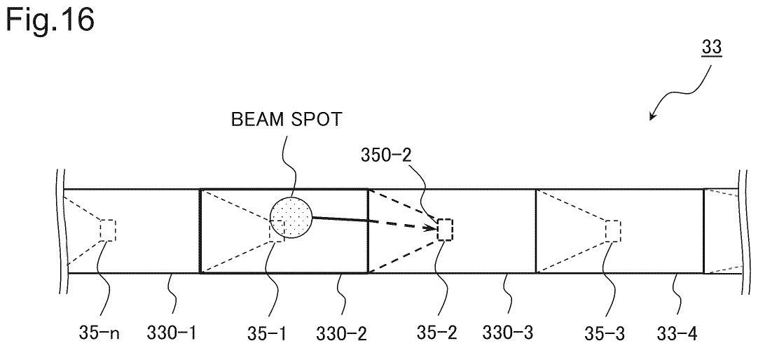

FIG. 16 is a conceptual diagram of part of the light guide 33 viewed from the ball lens 31. FIG. 16 illustrates an example in which the light guide 33 includes n base-units 330-1 to n (n is a natural number). In FIG. 16, portions behind the base-units 330-1 to n are indicated by broken lines. The light guide part of the base-unit 330-n is disposed behind the base-unit 330-1. The light receiving element 35-n of the base-unit 330-n is disposed behind the base-unit 330-1. The light guide part of the base-unit 330-1 is disposed behind the base-unit 330-2. The light receiving element 35-1 of the base-unit 330-1 is disposed behind the base-unit 330-2. The light guide part of the base-unit 330-2 is disposed behind the base-unit 330-3. The light receiving element 35-2 of the base-unit 330-2 is disposed behind the base-unit 330-3. The light guide part of the base-unit 330-3 is disposed behind the base-unit 330-4. The light receiving element 35-3 of the base-unit 330-3 is disposed behind the base-unit 330-4.

FIG. 16 illustrates a beam spot of the optical signal collected by the ball lens 31 and a path of the optical signal traveling while being reflected by the reflection face of the base-unit 330. In the example of FIG. 16, an optical signal with which the incident face of the base-unit 330-2 is irradiated is reflected toward the light receiving element 35-2 by the incident face. The optical signal reflected toward the light receiving element 35-2 is reflected by the back face (convex face) of the base-unit 330-3 and the light guide part of the base-unit 330-2, and travels toward the light receiving unit 350-2 of the light receiving element 35-2.

For example, the base-unit 330 is achieved by a material such as glass, plastic, or metal having a mirror surface formed on a face thereof. The material of the base-unit 330 is not limited as long as it can reflect an optical signal. For example, the range 360 exposed to the outside of the second face of the base-unit 330 may not be a mirror surface in order to prevent irregular reflection of the spatial optical signal.

The light receiving element 35 has a configuration similar to that of the light receiving element 15 of the first example embodiment. Each of the plurality of light receiving elements 35 is disposed at the end portion of the other end (light guide part) of the first face of the light guide 33, the plurality of light receiving elements being in association with the plurality of respective base-units 330 constituting the light guide 33 and. The light receiving element 35 includes a light receiving unit 350 that receives an optical signal derived from a spatial optical signal to be received. The light receiving element 35 is disposed in such a way that the light receiving unit 350 is substantially perpendicular to the first face at a terminal portion of the other end of the first face of the base-unit 330. The traveling direction of the optical signal collected by the ball lens 31 is changed by the light guide 33, and the optical signal is received by the light receiving unit 350 of the light receiving element 35.

The light receiving element 35 converts the received optical signal into an electric signal. Light receiving element 35 outputs the converted electric signal to a reception circuit (not illustrated). A configuration including the reception circuit will be described later.

### (Modifications)

Next, the modifications of the present example embodiment will be described with reference to the drawings. In the following modification, the plurality of base-units constituting the light guide of the reception device of the first and second example embodiments is disposed like the plurality of base-units constituting the light guide of the reception device of the present example embodiment. That is, in the following modification, the light guide directions of the plurality of base-units constituting the light guide of the reception device of the first and second example embodiments are aligned with the circumferential direction of the ball lens. Hereinafter, an example of replacing the light guide 33 of the reception device 3 of the present example embodiment will be described. The ball lens 31 and the light receiving element 35 will not be described.

### [First Modification]

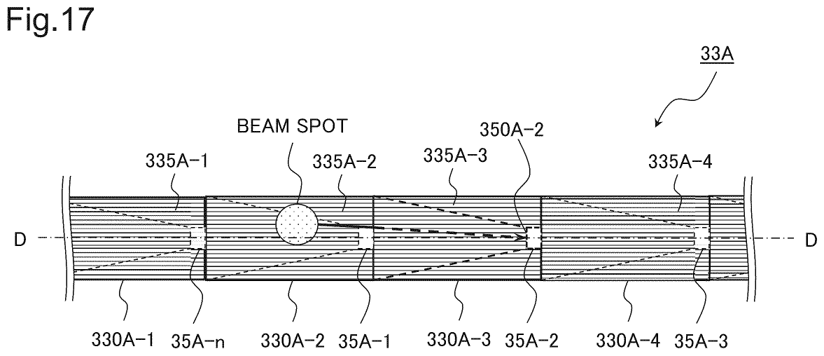

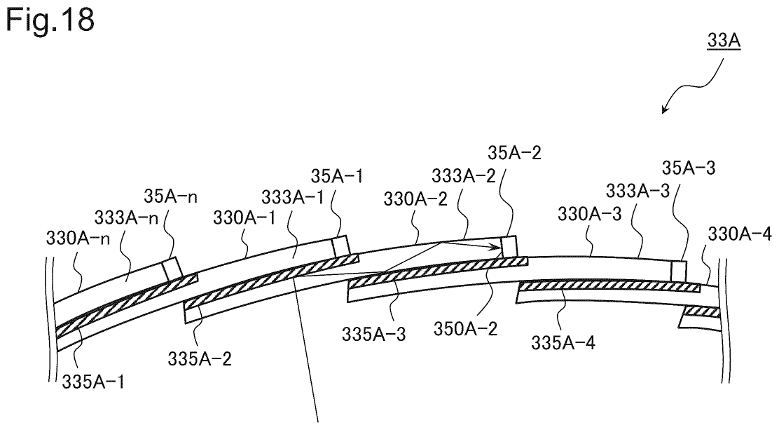

FIGS. 17 to 18 are conceptual diagrams for describing a configuration of a light guide 33A included in a reception device of the first modification. FIG. 17 is a conceptual diagram of part of the light guide 33A viewed from the ball lens 31. FIG. 18 is a sectional view taken along line D-D in FIG. 17. FIGS. 17 to 18 illustrate an example in which the light guide 33A includes n base-units 330A-1 to n (n is a natural number). The base-unit 330A includes a light guide body 333A and a diffraction element 335A. Each of the light guide body 333A and the diffraction element 335A has a configuration similar to the related configuration of the first example embodiment.

The base-unit 330A has a structure in which the base-unit 130 of the first example embodiment is laterally laid down. In FIG. 17, portions behind the base-units 330A-1 to n are indicated by broken lines.

The light guide 33A is disposed in such a way as to surround the periphery of the ball lens 31. The light guide 33A includes a plurality of base-units 330A-1 to n. Each base-unit 330A includes a light guide body 333A and a diffraction element 335A. The basic configurations of the light guide body 333A and the diffraction element 335A are similar to those of the first example embodiment. Unlike the first example embodiment, the light guide body 333A and the diffraction element 335A have a bent shape in accordance with the condensing region of the ball lens 31. The light guide body 333A is a main body of the base-unit 330A.

The light guide body 333A has a first face (concave face) facing the ball lens 31 and a second face (convex face) facing the first face. An incident face is formed on part (incident portion) of the first face of the light guide body 333A. The incident portion is provided on part of the first face of the light guide body 333A. The remaining portion (light guide part) of the first face of the light guide body 333A is disposed behind the adjacent base-unit 330A. An emission face (also referred to as an emission end) is provided on part of the side face of the light guide body 333A. The light receiving element 35A is disposed on the emission face of the light guide body 333A. The light receiving element 35A has a configuration similar to that of the light receiving element 15 of the first example embodiment. The light guide part of the light guide body 333A is tapered toward the light receiving element 35A in such a way that the cross-sectional area gradually decreases.

The plurality of base-units 330A is disposed with the concave first face facing the ball lens 31. One end of the first face of the base-unit 330A functions as an incident face. The other end of the first face functions as a light guide part. The base-unit 330A is disposed with one end and the other end of the first face being in accordance with the circumferential direction of the ball lens 31. One end (incident face) of the first face of the base-unit 330A faces the ball lens 31. The emission face of the base-unit 330A is disposed opposite to the second face of the adjacent base-unit 330A. The light receiving element 35A is disposed on part of the side face of the base-unit 330A. The light receiving element 35A is disposed in such a way that the light receiving face is substantially perpendicular to the first face in the emission face of the base-unit 330A. The plurality of base-units 330A surround the periphery of the ball lens 31 while each base-unit overlapping the adjacent base-units 330A.

The light guide part of the light guide body 333A-n of the base-unit 330A-n is disposed behind the light guide body 333A-1 of the base-unit 330A-1. The light receiving elements 35A-n of the base-unit 330A-n are disposed behind the light guide body 333A-1 of the base-unit 330A-1. The light guide part of the light guide body 333A-1 of the base-unit 330A-1 is disposed behind the light guide body 333A-2 of the base-unit 330A-2. The light receiving element 35A-1 of the base-unit 330A-1 is disposed behind the light guide body 333A-2 of the base-unit 330A-2. The light guide part of the light guide body 333A-2 of the base-unit 330A-2 is disposed behind the light guide body 333A-3 of the base-unit 330A-3. The light receiving element 35A-2 of the base-unit 330A-2 is disposed behind the light guide body 333A-3 of the base-unit 330A-3. The light guide part of the light guide body 333A-3 of the base-unit 330A-3 is disposed behind the light guide body 333A-4 of the base-unit 330A-4. The light receiving element 35A-3 of the base-unit 330A-3 is disposed behind the light guide body 333A-4 of the base-unit 330A-4.

FIGS. 17 to 18 illustrate a beam spot of the optical signal collected by the ball lens 31 and a path of the optical signal traveling while being reflected by the reflection face of the base-unit 330A. In the examples of FIGS. 17 to 18, the optical signal with which the incident face of the base-unit 330A-2 is irradiated is diffracted by the diffraction element 335A-2 facing the incident face, and travels toward the light receiving unit 350A-2 of the light receiving element 35A-2. The optical signal diffracted by the diffraction element 335A-2 is reflected by the first face and the second face of the light guide part of the base-unit 330A-3 behind the base-unit 330A-2, and travels toward the light receiving unit 350A-2 of the light receiving element 35A-2.

### [Second Modification]

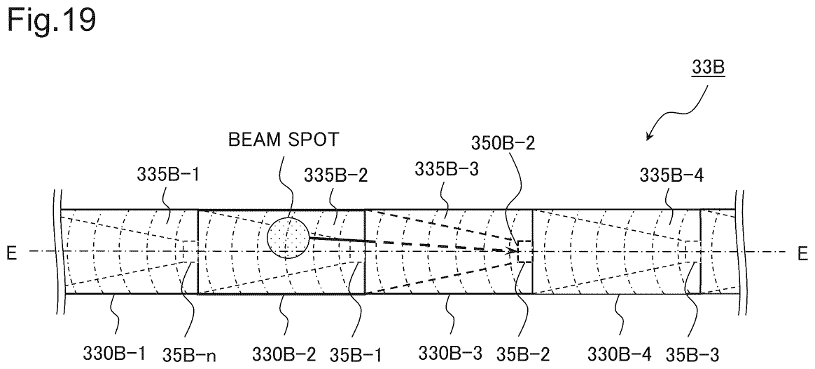

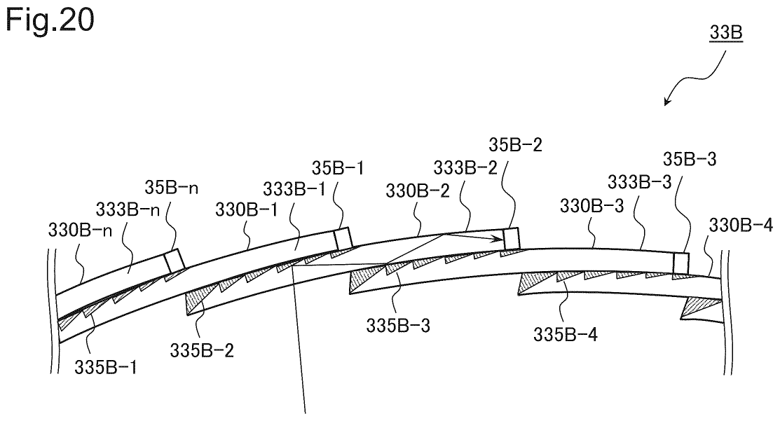

FIGS. 19 to 20 are conceptual diagrams for describing a configuration of a light guide 33B included in a reception device of the second modification. FIG. 19 is a conceptual diagram of part of the light guide 33B viewed from the ball lens 31. FIG. 20 is a sectional view taken along line E-E in FIG. 19. FIGS. 19 to 20 illustrate an example in which the light guide 33B includes n base-units 330B-1 to n (n is a natural number). The base-unit 330B includes a light guide body 333B and a multi-mirror 335B. Each of the light guide body 333B and the multi-mirror 335B has a configuration similar to the related configuration of the first example embodiment. The base-unit 330B has a structure in which the base-unit 230 of the second example embodiment is laid down. In FIG. 19, portions behind the base-units 330B-1 to n are indicated by broken lines.

The light guide body 333B has a first face (concave face) facing the ball lens 31 and a second face (convex face) facing the first face. An incident face is formed on part (incident portion) of the first face of the light guide body 333B. The incident portion is provided on part of the first face of the light guide body 333B. The remaining portion (light guide part) of the first face of the light guide body 333B is disposed behind the adjacent base-unit 330B. An emission face is provided on part of the side face of the light guide body 333B. The light receiving element 35B is disposed on the emission face of the light guide body 333B. The light receiving element 35B has a configuration similar to that of the light receiving element 15 of the first example embodiment. The light guide part of the light guide body 333B is tapered toward the light receiving element 35B in such a way that the cross-sectional area gradually decreases.

The plurality of base-units 330B is disposed with the concave first face facing the ball lens 31. One end of the first face of the base-unit 330B functions as an incident face. The other end of the first face functions as a light guide part. The base-unit 330B is disposed with one end and the other end of the first face being in accordance with the circumferential direction of the ball lens 31. One end (incident face) of the first face of the base-unit 330B faces the ball lens 31. The emission face of the base-unit 330B is disposed opposite to the second face of the adjacent base-unit 330B. The light receiving element 35B is disposed on part of the side face of the base-unit 330B. The light receiving element 35B is disposed in such a way that the light receiving face is substantially perpendicular to the first face in the emission face of the base-unit 330B. The plurality of base-units 330B surrounds the periphery of the ball lens 31 while each base-unit overlapping the adjacent base-units 330B.

The light guide part of the light guide body 333B-n of the base-unit 330B-n is disposed behind the light guide body 333B-1 of the base-unit 330B-1. The light receiving element 35B-n of the base-unit 330B-n is disposed behind the light guide body 333B-1 of the base-unit 330B-1. The light guide part of the light guide body 333B-1 of the base-unit 330B-1 is disposed behind the light guide body 333B-2 of the base-unit 330B-2. The light receiving element 35B-1 of the base-unit 330B-1 is disposed behind the light guide body 333B-2 of the base-unit 330B-2. The light guide part of the light guide body 333B-2 of the base-unit 330B-2 is disposed behind the light guide body 333B-3 of the base-unit 330B-3. The light receiving element 35B-2 of the base-unit 330B-2 is disposed behind the light guide body 333B-3 of the base-unit 330B-3. The light guide part of the light guide body 333B-3 of the base-unit 330B-3 is disposed behind the light guide body 333B-4 of the base-unit 330B-4. The light receiving element 35B-3 of the base-unit 330B-3 is disposed behind the light guide body 333B-4 of the base-unit 330B-4.

FIGS. 19 to 20 illustrate a beam spot of the optical signal collected by the ball lens 31 and a path of the optical signal traveling while being reflected by the reflection face of the base-unit 330B. In the examples of FIGS. 19 to 20, the optical signal with which the incident face of the base-unit 330B-2 is irradiated is reflected by the multi-mirror 335B facing the incident face, and travels toward the light receiving unit 350B-2 of the light receiving element 35B-2. The optical signal reflected by the multi-mirror 335B is reflected by the first face and the second face of the light guide part of the base-unit 330B-3 behind the base-unit 330B-2, and travels toward the light receiving unit 350B-2 of the light receiving element 35B-2.

As described above, the reception device of the present example embodiment includes the ball lens, the light guide, and the plurality of light receiving elements. The ball lens collects the optical signal propagating in the space. The light guide includes a plurality of base-units annularly disposed around the ball lens. The base-unit includes a concave curved face including an incident face that reflects an optical signal, a convex curved face facing the concave curved face, and an emission end to which the optical signal incident on the incident face is guided. The plurality of base-units is disposed with a concave curved face facing the ball lens in such a way as to guide the optical signal incident on the incident face in a direction along the circumferential direction of the circle formed by the array of the plurality of base-units. An emission end of each of the plurality of base-units is disposed close to a convex curved face of an adjacent base-unit. The light receiving element includes a light receiving unit that receives light in a wavelength region of an optical signal. The light receiving element is disposed with the light receiving unit facing the emission end of the base-unit. The light receiving element receives the optical signal reflected and guided by the concave curved face of the associated base-unit and the convex curved face of the base-unit adjacent to the associated base-unit. The light receiving element outputs a signal derived from the received optical signal.

A reception device of the present example embodiment reflects an optical signal incident on an incident face of a base-unit by a concave curved face of the base-unit and a convex curved face of a base-unit adjacent to the base-unit, and guides the optical signal along a circumferential direction of a circle formed by an array of a plurality of base-units. According to the reception device of the present example embodiment, since the optical signal coming from various directions is guided along the circumferential direction of the circle formed by the arrangement of the plurality of base-units, the thickness of the light guide can be reduced. Therefore, according to the reception device of the present example embodiment, the light reception range in the thickness direction of the light guide is widened.

### Fourth Example Embodiment

Next, a reception device according to a fourth example embodiment will be described with reference to the drawings. The reception device of the present example embodiment is different from that of each of the first to third example embodiments in the configuration of the light guide part. The drawings used in the description of the present example embodiment are conceptual and do not accurately depict an actual structure.

### (Configuration)

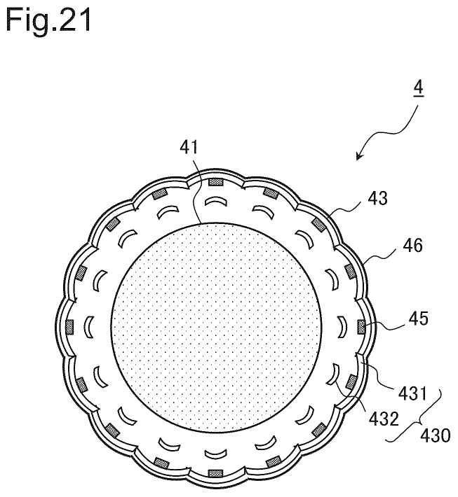

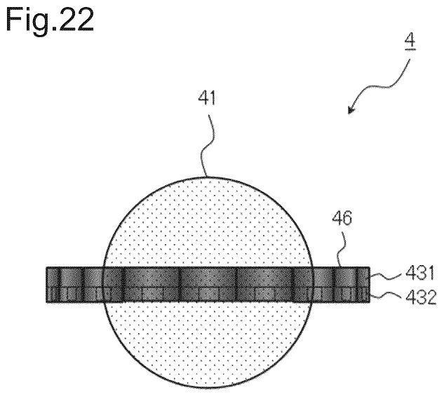

FIGS. 21 to 22 are conceptual diagrams illustrating an example of a configuration of a reception device 4 according to the present example embodiment. The reception device 4 includes a ball lens 41, a light guide 43, a plurality of light receiving elements 45, and a light shielding band 46. FIG. 21 is a plan view of the reception device 4 when viewed from above. FIG. 22 is a side view of the reception device 4 when viewed in the lateral direction. FIG. 22 illustrates a configuration hidden by the light shielding band 46 (first curved face mirror 431, the second curved face mirror 432) is indicated by a broken line. A positional relationship between the ball lens 41 and the light guide 43 is fixed by a support (not illustrated). In the present example embodiment, the support for fixing the light guide 43 to the ball lens 41 is omitted.

The ball lens 41 has a configuration similar to that of the ball lens 11 of the first example embodiment. The ball lens 41 collects a spatial optical signal coming from the outside on a condensing region of the ball lens 41.

The light guide 43 is disposed in the condensing region of the ball lens 41 in such a way as to surround the periphery of the ball lens 41. The light guide 43 includes a plurality of base-units 430. The base-unit 430 includes the first curved face mirror 431 and the second curved face mirror 432.

The first curved face mirror 431 has a concave face in which a reflection face is formed. The concave face (reflection face) of the first curved face mirror 431 faces the ball lens 41. The light receiving element 45 is disposed on part of the concave face (reflection face) of the first curved face mirror 431. The optical signal collected by the ball lens 41 is incident on the concave face (reflection face) of the first curved face mirror 431. The optical signal incident on the concave face (reflection face) of the first curved face mirror 431 is reflected toward second curved face mirror 432.

For example, the first curved face mirror 431 is made of a material such as glass, plastic, or metal in which a mirror surface is formed on a concave face. The material of the first curved face mirror 431 is not limited as long as the optical signal can be reflected by the concave face (reflection face). A treatment for preventing reflection of light or a treatment for absorbing light may be applied to the convex face facing the concave face (reflection face) of the first curved face mirror 431 in order to prevent irregular reflection of a spatial optical signal coming from the outside. For example, a layer that absorbs light may be formed on the convex face of the first curved face mirror 431.

The second curved face mirror 432 has a convex face in which a reflection face is formed. The convex face (reflection face) of the second curved face mirror 432 faces the concave face (reflection face) of the first curved face mirror 431. The convex face (reflection face) of the second curved face mirror 432 faces the light receiving element 45. The optical signal reflected by the concave face (reflection face) of the first curved face mirror 431 is incident on the convex face (reflection face) of the second curved face mirror 432. The optical signal incident on the convex face (reflection face) of the second curved face mirror 432 is reflected toward the light receiving element 45.

For example, the second curved face mirror 432 is made of a material such as glass, plastic, or metal in which a mirror surface is formed on a convex face. The material of the second curved face mirror 432 is not limited as long as the optical signal can be reflected by the convex face (reflection face). A treatment for preventing reflection of light or a treatment for absorbing light may be applied to the concave face facing the convex face (reflection face) of the second curved face mirror 432 in order to prevent irregular reflection of the optical signal collected by the ball lens 41. For example, a layer that absorbs light may be formed on the concave face of the second curved face mirror 432.

The light shielding band 46 is disposed in such a way as to cover the first curved face mirror 431 and the second curved face mirror 432. The light shielding band 46 prevents the spatial optical signal from entering the ball lens 41 from the positions of the first curved face mirror 431 and the second curved face mirror 432. A treatment for preventing reflection of light or a treatment for absorbing light is preferably added to the surface of the light shielding band 46 in order to prevent irregular reflection of the spatial optical signal. For example, the light shielding band 46 is achieved by a material that easily absorbs light in the wavelength band of the spatial optical signal. The first curved face mirror 431 or the second curved face mirror 432 and the light shielding band 46 may be disposed at an interval or may be in close contact with each other. When a treatment for preventing reflection of light or a treatment for absorbing light is applied to the convex face of the first curved face mirror 431 or the concave face of the second curved face mirror 432, the light shielding band 46 may be omitted.

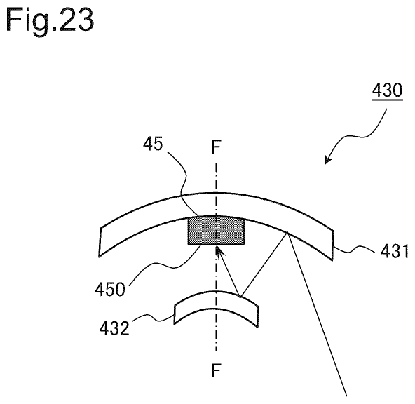

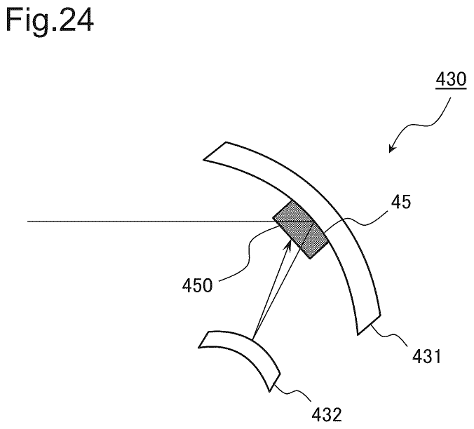

FIGS. 23 to 24 are conceptual diagrams for describing an example of the base-unit 430 constituting the light guide 43. FIG. 23 is a plan view of the base-unit 430. FIG. 24 is a sectional view of the base-unit 430 taken along line F-F in FIG. 23. FIGS. 23 to 24 illustrate an example of a path of an optical signal entering the base-unit 430.

Most of the optical signal collected by the ball lens 41 is incident on the concave face (reflection face) of the first curved face mirror 431. The optical signal incident on the concave face (reflection face) of the first curved face mirror 431 is reflected toward the convex face (reflection face) of the second curved face mirror 432. The optical signal incident on the convex face (reflection face) of the second curved face mirror 432 is reflected toward the light receiving element 45. Among the optical signal reflected by the convex face (reflection face) of the second curved face mirror 432, the optical signal incident on a light receiving unit 450 of the light receiving element 45 is received by a light receiving element 45. Among the optical signal collected by the ball lens 41, the optical signal directly incident on the light receiving unit 450 of the light receiving element 45 is received by the light receiving element 45. Among the optical signal collected by the ball lens 41, the optical signal incident on the concave face of the second curved face mirror 432 is not received by the light receiving element 45.

The light receiving element 45 has a configuration similar to that of the light receiving element 15 of the first example embodiment. Each of the plurality of light receiving elements 45 is disposed on part of a concave face (reflection face) of the first curved face mirror 431 of each of the plurality of base-units 430 constituting light guide 43. The light receiving element 45 includes the light receiving unit 450 that receives an optical signal derived from a spatial optical signal to be received. The light receiving unit 450 of each light receiving element 45 faces a reflection face (convex face) of the second curved face mirror 432 of the base-unit 430. The traveling direction of the optical signal collected by the ball lens 41 is changed by the light guide 43, and the optical signal is received by the light receiving unit 450 of the light receiving element 45.

The light receiving element 45 converts the received optical signal into an electric signal. Light receiving element 45 outputs the converted electric signal to a reception circuit (not illustrated). A configuration including the reception circuit will be described later.

### (Modifications)

Next, the modifications of the present example embodiment will be described with reference to the drawings. In the drawings of the following modifications, the same reference numerals as those in FIGS. 21 to 24 are used for the same configurations as those in FIGS. 21 to 24. Description of configurations similar to those in FIGS. 21 to 24 may be omitted.

### [Third Modification]

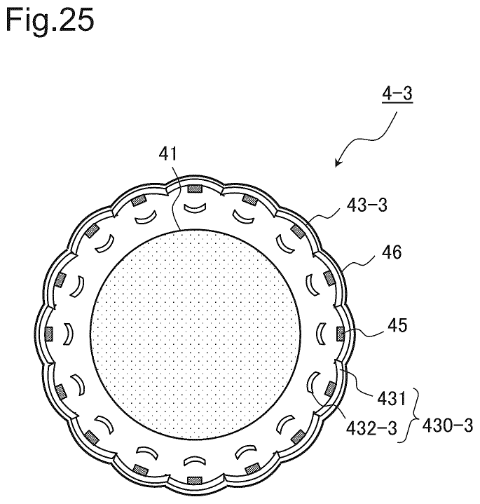

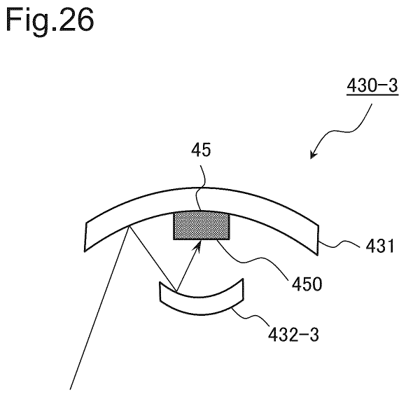

FIGS. 25 to 26 are conceptual diagrams for describing a configuration of a reception device 4-3 of the third modification. The reception device 4 includes a ball lens 41, a light guide 43-3, a plurality of light receiving elements 45, and a light shielding band 46. In the present modification, the reflection face is formed on the concave face of the second curved face mirror constituting the base-unit. The light guide 43-3 includes a plurality of base-units 430-3. FIG. 25 is a plan view of the reception device 4-3 when viewed from above. FIG. 26 is an enlarged view of the base-unit 430-3.

The light guide 43-3 is disposed in the condensing region of the ball lens 41 in such a way as to surround the periphery of the ball lens 41. The light guide 43-3 includes a plurality of base-units 430-3. The base-unit 430-3 includes the first curved face mirror 431 and the second curved face mirror 432-3.

The first curved face mirror 431 has a concave face in which a reflection face is formed. The concave face (reflection face) of the first curved face mirror 431 faces the ball lens 41. The light receiving element 45 is disposed on part of the concave face (reflection face) of the first curved face mirror 431. The optical signal collected by the ball lens 41 is incident on the concave face (reflection face) of the first curved face mirror 431. The optical signal incident on the concave face (reflection face) of the first curved face mirror 431 is reflected toward second curved face mirror 432. A treatment for preventing reflection of light or a treatment for absorbing light may be applied to the convex face of the first curved face mirror 431 in order to prevent irregular reflection of a spatial optical signal coming from the outside. For example, a layer that absorbs light may be formed on the convex face of the first curved face mirror 431.

The second curved face mirror 432-3 has a concave face in which a reflection face is formed. The concave face (reflection face) of the second curved face mirror 432-3 faces the concave face (reflection face) of the first curved face mirror 431. The concave face (reflection face) of the second curved face mirror 432-3 faces the light receiving element 45. The optical signal reflected by the concave face (reflection face) of the first curved face mirror 431 is incident on the concave face (reflection face) of the second curved face mirror 432-3. The optical signal incident on the concave face (reflection face) of the second curved face mirror 432-3 is reflected toward the light receiving element 45. A treatment for preventing reflection of light or a treatment for absorbing light may be applied to the convex face of the second curved face mirror 432-3 in order to prevent irregular reflection of the optical signal collected by the ball lens 41. For example, a layer that absorbs light may be formed on the convex face of the second curved face mirror 432-3.

The light receiving element 45 is disposed on part of a concave face (reflection face) of the first curved face mirror 431 of the base-unit 430-3. The light receiving element 45 includes the light receiving unit 450 that receives an optical signal derived from a spatial optical signal to be received. The light receiving unit 450 faces a reflection face (concave face) of the second curved face mirror 432-3 of the base-unit 430-3. For example, the light receiving unit 450 is disposed at a focal position of the reflection face (concave face) of the second curved face mirror.

The light shielding band 46 is disposed in such a way as to cover the first curved face mirror 431 and the second curved face mirror 432. The light shielding band 46 prevents the spatial optical signal from entering the ball lens 41 from the positions of the first curved face mirror 431 and the second curved face mirror 432. When a treatment for preventing reflection of light or a treatment for absorbing light is applied to the convex face of the first curved face mirror 431 or the convex face of the second curved face mirror 432, the light shielding band 46 may be omitted.

In the present modification, since the focal position of the second curved face mirror 432-3 is clearly determined, it is easy to design the curved faces of the first curved face mirror 431 and the second curved face mirror 432-3 and to determine the position where the light receiving element 45 is disposed.

### [Fourth Modification]

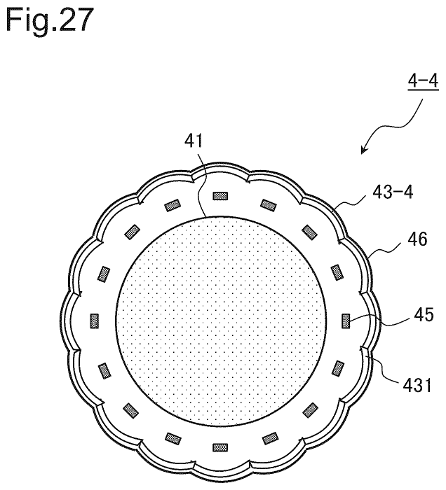

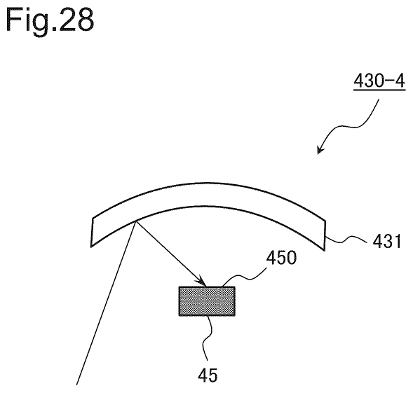

FIGS. 27 to 28 are conceptual diagrams for describing a configuration of a reception device 4-4 of the fourth modification. The reception device 4 includes a ball lens 41, a light guide 43-4, a plurality of light receiving elements 45, and a light shielding band 46. In the present modification, the second curved face mirror 432 is omitted, and the light receiving element 45 is disposed at the position of the second curved face mirror 432. The light guide 43-4 includes a plurality of base-units 430-4 (first curved face mirrors 431). FIG. 27 is a plan view of the reception device 4-4 when viewed from above. FIG. 28 is an enlarged view of part of the base-unit 430-4.

The light guide 43-4 is disposed in the condensing region of the ball lens 41 in such a way as to surround the periphery of the ball lens 41. The light guide 43-4 includes a plurality of base-units 430-4 (first curved face mirrors 431). The base-unit 430-4 is single first curved face mirror 431.

The first curved face mirror 431 has a concave face in which a reflection face is formed. The concave face (reflection face) of the first curved face mirror 431 faces the ball lens 41. The optical signal collected by the ball lens 41 is incident on the concave face (reflection face) of the first curved face mirror 431. The optical signal incident on the concave face (reflection face) of the first curved face mirror 431 is reflected toward the light receiving unit 450 of the light receiving element 45. A treatment for preventing reflection of light or a treatment for absorbing light may be applied to the convex face of the first curved face mirror 431 in order to prevent irregular reflection of a spatial optical signal coming from the outside. For example, a layer that absorbs light may be formed on the convex face of the first curved face mirror 431.

Light receiving element 45 is disposed with its light receiving face facing a concave face (reflection face) of the first curved face mirror 431. A face (also referred to as a back face) facing the light receiving face of the light receiving element 45 faces the ball lens 41. The light receiving unit 450 of the light receiving element 45 faces a concave face (reflection face) of the first curved face mirror 431. For example, the light receiving unit 450 is disposed at a focal position of the reflection face (concave face) of the first curved face mirror 431. A treatment for preventing reflection of light may be added to the back face of the light receiving element 45 in order to prevent irregular reflection of the optical signal. For example, a layer that absorbs an optical signal is formed on the back face of the light receiving element 45. For example, a configuration similar to that of the light shielding band 46 may be disposed on the back face of the light receiving element 45 in order to prevent the optical signal collected by the ball lens 41 from being irregularly reflected. In such a configuration, a light absorbing layer may be formed on a side face facing the ball lens 41.

Light shielding band 46 is disposed in such a way as to cover a periphery of the first curved face mirror 431. The light shielding band 46 prevents the spatial optical signal from entering the ball lens 41 from the position of the first curved face mirror 431. When a treatment for preventing reflection of light or a treatment for absorbing light is applied to the convex face of the first curved face mirror 431 or the back face of the light receiving element 45, the light shielding band 46 may be omitted.

In the present modification, the second curved face mirror 432 is omitted, and the light receiving element 45 is disposed at the position of the second curved face mirror 432. The reception device 4-4 of the present modification can efficiently receive an optical signal with a simple configuration. In the present modification, the light receiving element 45 is only required to be disposed at the focal position of the first curved face mirror 431, so that the curved face of the first curved face mirror 431 can be easily designed.

As described above, the reception device of the present example embodiment includes the ball lens, the light guide, and the plurality of light receiving elements. The ball lens collects the optical signal propagating in the space. The light guide includes a plurality of base-units annularly disposed around the ball lens.

The base-unit includes a first curved face mirror including an incident face that reflects an optical signal, and a second curved face mirror having a reflection face facing the first curved face mirror. The plurality of the first curved face mirrors is disposed with the incident face facing the ball lens.

The plurality of light receiving elements is associated with the plurality of respective base-units. The light receiving element receives an optical signal emitted from the base-unit. The light receiving element is disposed on the same curved face as the incident face of the first curved face mirror of the associated base-unit with the light receiving unit that receives the light in the wavelength region of the optical signal facing the reflection face of the second curved face mirror. The light receiving element outputs a signal derived from the received optical signal.

In the reception device of the present example embodiment, the first curved face mirror and the second curved face mirror constituting the plurality of base-units constituting the light guide the optical signals coming from various directions toward the light receiving element disposed on the concave face of the first curved face mirror of the base-unit. According to the reception device of the present example embodiment, since the optical signal coming from various directions can be collectively received by each base-unit constituting the light guide, the number of light receiving elements can be reduced. Therefore, according to the reception device of the present example embodiment, the optical signal coming from various directions can be received using an appropriate number of light receiving elements.

In an aspect of the present example embodiment, the base-unit includes a first curved face mirror including an incident face that reflects an optical signal. The plurality of the first curved face mirrors is disposed with the incident face facing the ball lens. The light receiving element is disposed with the light receiving unit that receives light in a wavelength region of an optical signal facing a reflection face of the first curved face mirror of the associated base-unit. According to the present aspect, by omitting the second curved face mirror and disposing the light receiving element at the position of the second curved face mirror, an optical signal can be efficiently received with a simple configuration.

### Fifth Example Embodiment

Next, a reception device according to a fifth example embodiment will be described with reference to the drawings. The reception device of the present example embodiment has a configuration in which a light guide auxiliary device that assists the optical signal collected by the ball lens to be guided to the light guide part is added to the reception device of each of the first to fourth example embodiments.

### (Configuration)

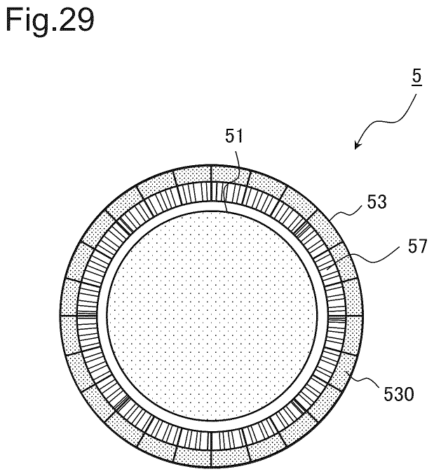

FIG. 29 is a conceptual diagram illustrating an example of a configuration of a reception device 5 according to the present example embodiment. The reception device 5 includes a ball lens 51, a light guide 53, a plurality of light receiving elements (not illustrated), and a light guide auxiliary device 57. FIG. 29 is a plan view of the reception device 5 when viewed from above. A side view of the reception device 5 when viewed in the lateral direction is omitted. A positional relationship between the ball lens 51, the light guide 53, and the light guide auxiliary device 57 is fixed by a support (not illustrated). In the present example embodiment, a support for fixing the light guide 53 and the light guide auxiliary device 57 to the ball lens 51 is omitted.

The ball lens 51 has a configuration similar to that of the ball lens 11 of the first example embodiment. The ball lens 51 collects a spatial optical signal coming from the outside on a condensing region of the ball lens 51.

Light guide auxiliary device 57 has an annular shape. The light guide auxiliary device 57 is disposed between the ball lens 51 and the light guide 53. The light guide auxiliary device 57 is disposed in such a way as to surround a periphery of the ball lens 51. The light guide auxiliary device 57 has an inner face along the inner diameter and an outer face along the outer diameter. The optical signal collected by the ball lens 51 is incident on the inner face of the light guide auxiliary device 57. The optical signal having entered the light guide auxiliary device 57 travels toward the outer face. The optical signal reaching the outer face of the light guide auxiliary device 57 is emitted toward the light guide 53. A configuration example of achieving the light guide auxiliary device 57 will be described later.

The light guide 53 is any one of the light guides according to the first to fourth example embodiments. The light guide 53 is disposed in such a way as to surround the periphery of the light guide auxiliary device 57. The light guide 53 includes a plurality of base-units 530. The optical signal emitted from the light guide auxiliary device 57 is incident on the light guide 53. The light guide 53 guides the incident optical signal toward a light receiving element (not illustrated).

The light receiving element (not illustrated) has a configuration similar to that of the light receiving element 15 of the first example embodiment. Each of the plurality of light receiving elements is disposed in association with each of the plurality of base-units constituting the light guide 53. The optical signal collected by the ball lens 51 reaches the light guide 53 via the light guide auxiliary device 57. The traveling direction of the optical signal reaching the light guide 53 is changed by the light guide 53, and the optical signal is received by the light receiving element. The light receiving element converts the received optical signal into an electric signal. The light receiving element outputs the converted electric signal to a reception circuit (not illustrated).

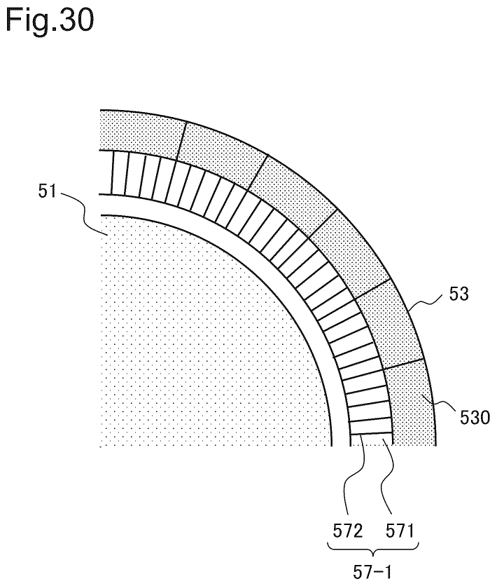

FIG. 30 is a conceptual diagram illustrating an example of a configuration (light guide auxiliary device 57-1) for achieving the light guide auxiliary device 57. The light guide auxiliary device 57-1 includes a plurality of transparent layers 571 and a plurality of shielding layers 572. The transparent layer 571 is made of an element having high transmittance in a wavelength band of an optical signal. For example, the transparent layer 571 can be made of a material such as glass or plastic. The material of the transparent layer 571 is not limited as long as the transmittance is high in the wavelength band of the optical signal. The shielding layer 572 is a layered element including an element having a high absorption rate in a wavelength band of an optical signal. For example, the shielding layer 572 can be achieved by a material such as carbon or plastic. The light guide auxiliary device 57-1 has a structure in which the plurality of transparent layers 571 and the plurality of shielding layers 572 are alternately adjacent in the circumferential direction of the ball lens 51.

Of the optical signal that has entered the inner face of the light guide auxiliary device 57-1, the component that has not hit the shielding layer 572 is emitted from the outer face and enters the light guide 53. Of the optical signal that has entered the inner face of the light guide auxiliary device 57-1, the component that has hit the shielding layer 572 is absorbed by the shielding layer 572. The optical signal absorbed by the shielding layer 572 is not emitted from the outer face of the light guide auxiliary device 57-1. That is, the shielding layer 572 blocks stray light between the ball lens 51 and the light guide 53. When the thickness of the light guide auxiliary device 57-1 is too thick, the optical signal absorbed by the shielding layer 572 increases. Therefore, the thickness of light guide auxiliary device 57-1 is preferably set according to the balance between the effect of blocking the stray light and the absorption amount of the optical signal by the shielding layer 572.

In the configuration of the light guide auxiliary device 57-1 (FIG. 30), the plurality of shielding layers 572 is disposed for each base-unit 530. Therefore, according to the configuration of the light guide auxiliary device 57-1 (FIG. 30), the optical signal can be prevented from being received across by the light receiving elements related to the adjacent base-units 530.

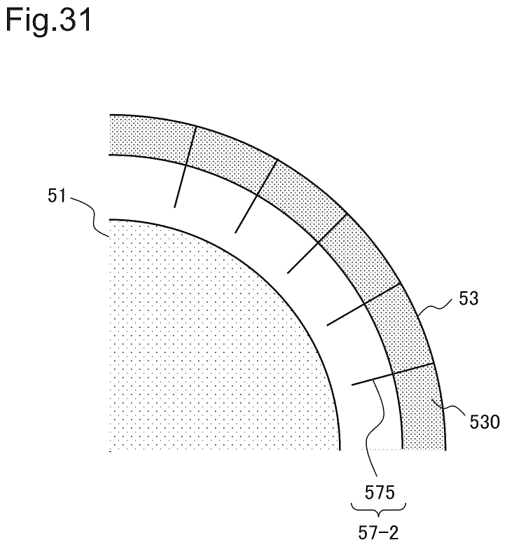

FIG. 31 is a conceptual diagram illustrating another example (light guide auxiliary device 57-2) of the configuration for achieving the light guide auxiliary device 57. The light guide auxiliary device 57-2 includes a plurality of partition walls 575. The partition wall 575 is disposed according to a boundary between adjacent base-units 530. For example, the partition wall 575 is made of an element having a high absorption rate in a wavelength band of an optical signal.

Of the optical signal that has entered the inner face of the light guide auxiliary device 57-2, the component that has not hit the partition wall 575 is emitted from the outer face and enters the light guide 53. When the light absorbing property of the partition wall 575 is high, the component that hits the partition wall 575 of the optical signal incident on the inner face of the light guide auxiliary device 57-2 is not emitted from the outer face.

In the configuration of light guide auxiliary device 57-2 (FIG. 31), the partition wall 575 is disposed between the adjacent base-units 530. Therefore, according to the configuration of the light guide auxiliary device 57-2 (FIG. 31), the optical signal can be prevented from being received across by the light receiving elements related to the adjacent base-units 530.

### (Modifications)

Next, the modifications of the present example embodiment will be described with reference to the drawings. In the following modification, the ball lens and the light guide auxiliary device are brought into close contact with each other. In the drawings of the following modifications, the same reference numerals as those in FIG. 29 are used for the same configurations as those in FIG. 29.

### [Fifth Modification]

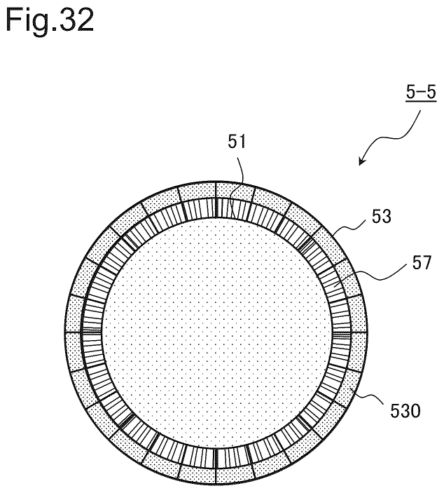

FIG. 32 is a conceptual diagram for describing a configuration of a reception device 5-5 of the fifth modification. The reception device 5-5 includes a ball lens 51, a light guide 53, a plurality of light receiving elements (not illustrated), and a light guide auxiliary device 57. The light guide 53 includes a plurality of base-units 530. FIG. 32 is a plan view of the reception device 5-5 when viewed from above. Since the components of the reception device 5-5 are similar to those in FIG. 29, detailed description thereof is omitted.

In the reception device 5-5, the outer periphery of the ball lens 51 and the inner face of the light guide auxiliary device 57 are in close contact with each other. In the case of the configuration of the reception device 5-5, the refractive index of the ball lens 51 and the refractive index of the transparent layer (not illustrated) included in the light guide auxiliary device 57 are preferably the same.

According to the configuration of the reception device 5-5 (FIG. 32), since there is no space between the ball lens 51 and the inner face of the light guide auxiliary device 57, the optical signal collected by the ball lens 51 is not reflected on the surface of the light guide auxiliary device 57. That is, according to the configuration of the reception device 5-5, the optical signal collected by the ball lens 51 hardly escape before reaching the light guide 53. Therefore, according to the configuration of the reception device 5-5, an optical signal can be received more efficiently.

As described above, the reception device of the present example embodiment includes the light guide auxiliary device that is disposed between the ball lens and the light guide and guides the optical signal collected by the ball lens toward the light guide. For example, the light guide auxiliary device includes a plurality of shielding layers disposed along the diameter direction of the ball lens, and a plurality of transparent layers formed between the plurality of shielding layers and through which an optical signal is transmitted. For example, the light guide auxiliary device includes a plurality of partition walls disposed along the diameter direction of the ball lens. For example, the light guide auxiliary device is disposed in close contact with the ball lens.

The reception device of the present example embodiment guides the optical signal collected by the ball lens to the light guide via the light guide auxiliary device. Therefore, according to the reception device of the present example embodiment, it is possible to receive the light more efficiently by more reliably guiding the optical signal collected by the ball lens to the light guide.

### Sixth Example Embodiment

Next, a reception device according to a sixth example embodiment will be described with reference to the drawings. The reception device of the present example embodiment has a configuration in which the reception circuit that decodes an optical signal received by a light receiving element is added to the reception device of each of the first to fourth example embodiments.

### (Configuration)

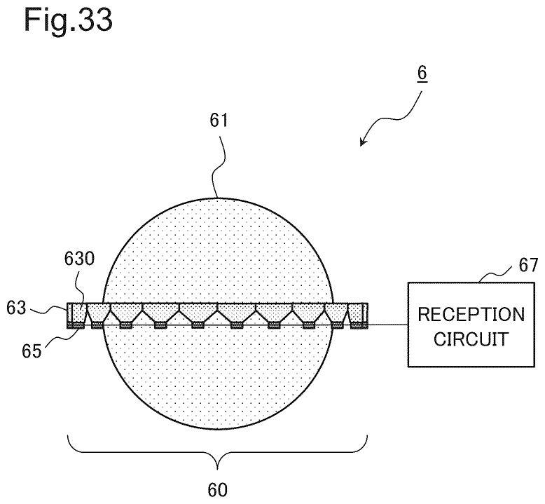

FIG. 33 is a conceptual diagram illustrating an example of a configuration of a reception device 6 according to the present example embodiment. The reception device 6 includes a ball lens 61, a light guide 63, a plurality of light receiving elements 65, and a reception circuit 67. FIG. 33 is a side view of the reception device 6 when viewed in the lateral direction. A plan view of the reception device 6 when viewed from above is omitted. A positional relationship between the ball lens 61 and the light guide 63 is fixed by a support (not illustrated). In the present example embodiment, the support for fixing the light guide 63 to the ball lens 61 is omitted.

The ball lens 61, the light guide 63, and the plurality of light receiving elements 65 constitute a light receiving unit 60. The light receiving unit 60 is any one of the reception devices according to the first to fifth example embodiments. FIG. 33 illustrates, as an example, a configuration in which the reception circuit 67 is added to the reception device 1 (corresponding to the light receiving unit 60) of the first example embodiment. The description of the configuration of the light receiving unit 60 is omitted.

The reception circuit 67 acquires a signal output from each of the plurality of light receiving elements 65. The reception circuit 67 amplifies a signal from each of the plurality of light receiving elements 65. The reception circuit 67 decodes the amplified signal and analyzes a signal from the communication target. For example, the reception circuit 67 is configured to collectively analyze signals of the plurality of light receiving elements 65. In a case where the signals of the plurality of light receiving elements 65 are collectively analyzed, it is possible to achieve the single-channel reception device 6 that communicates with a single communication target. For example, the reception circuit 67 is configured to individually analyze a signal for each of the plurality of light receiving elements 65. In a case where the signal is individually analyzed for each of the plurality of light receiving elements 65, it is possible to achieve the multi-channel reception device 6 that simultaneously communicates with a plurality of communication targets. The signal decoded by the reception circuit 67 is used for any purpose. The use of the signal decoded by the reception circuit 67 is not particularly limited.

### [Reception Circuit]

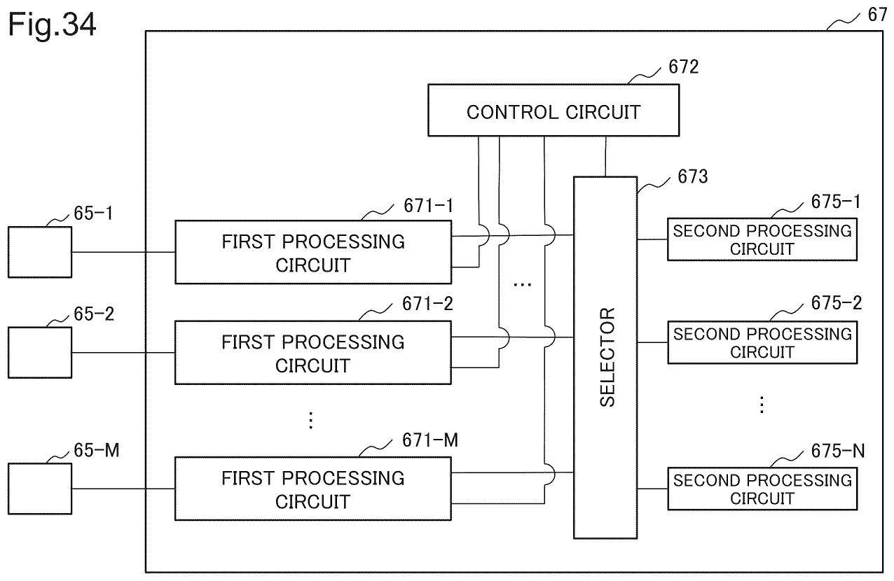

Next, an example of a detailed configuration of the reception circuit 67 included in the reception device 6 will be described with reference to the drawings. FIG. 34 is a block diagram illustrating an example of a configuration of the reception circuit 67. In the example of FIG. 34, the number of the plurality of light receiving elements 65 is M (M is a natural number). FIG. 34 is an example of the configuration of the reception circuit 67, and does not limit the configuration of the reception circuit 67.

The reception circuit 67 includes a plurality of first processing circuits 671-1 to M, a control circuit 672, a selector 673, and a plurality of second processing circuits 675-1 to N (M and N are natural numbers). The first processing circuit 671 is associated with any one of the plurality of light receiving elements 65-1 to M. The first processing circuit 671 may be configured for each group of the plurality of light receiving elements 65 included in the plurality of light receiving elements 65-1 to M.

For example, the first processing circuit 671 includes a high-pass filter (not illustrated). The high-pass filter acquires a signal from the light receiving element 65. The high-pass filter selectively transmits a signal of a high frequency component corresponding to the wavelength band of the spatial optical signal among the acquired signals. The high-pass filter cuts off a signal derived from ambient light such as sunlight. For example, instead of the high-pass filter, a band pass filter that selectively transmits a signal in a wavelength band of a spatial optical signal may be configured. When the light receiving element 65 is saturated with intense sunlight, an optical signal cannot be read. Therefore, a color filter that selectively passes the light in the wavelength band of the spatial optical signal may be installed before the light receiving unit of the light receiving element 65.

For example, the first processing circuit 671 includes an amplifier (not illustrated). The amplifier acquires the signal output from the high-pass filter. The amplifier amplifies the acquired signal. The amplification factor of the signal by the amplifier is not particularly limited.

For example, the first processing circuit 671 includes an output monitor (not illustrated). The output monitor monitors an output value of the amplifier. The output monitor outputs a signal exceeding a predetermined output value among the signals amplified by the amplifier to the selector 673. Among the signals input to the selector 673, the signal to be received is allocated to any one of the plurality of second processing circuits 675-1 to N under the control of the control circuit 672. The signal to be received is a spatial optical signal from a communication device (not illustrated) to be communicated. A signal from the light receiving element 65 that is not used for receiving the spatial optical signal is not output to the second processing circuit 675.

For example, the first processing circuit 671 may include an integrator (not illustrated) as an output monitor (not illustrated). The integrator acquires the signal output from the high-pass filter. The integrator integrates the acquired signal. The integrator outputs the integrated signal to the control circuit 672. The integrator is disposed to measure the intensity of the spatial optical signal received by the light receiving element 65. Since the intensity of the spatial optical signal received in a state where the beam diameter is not narrowed is weaker than that of the signal in a state where the beam diameter is narrowed, it is difficult to measure the voltage of the signal amplified only by the amplifier. By using an integrator, for example, by integrating a signal in a period of several milliseconds to several tens of milliseconds, the voltage of the signal can be increased to a level at which the voltage can be measured.

The control circuit 672 acquires a signal output from each of the plurality of first processing circuits 671-1 to M. In other words, the control circuit 672 acquires a signal derived from an optical signal received by each of the plurality of light receiving elements 65-1 to M. For example, the control circuit 672 compares the readings of the signals from the plurality of light receiving elements 65 adjacent to each other. The control circuit 672 selects the light receiving element 65 having the maximum signal intensity according to the comparison result. The control circuit 672 controls the selector 673 in such a way as to allocate the signal derived from the selected light receiving element 65 to any one of the plurality of second processing circuits 675-1 to N.

In a case where the position of the communication target is identified in advance, the processing of estimating the incoming direction of the spatial optical signal is not performed, and the signals output from the light receiving elements 65-1 to M may be output to any of the preset second processing circuits 675. On the other hand, when the position of the communication target is not specified in advance, the second processing circuit 675 as an output destination of the signals output from the light receiving elements 65-1 to M may be selected. For example, when the control circuit 672 selects the light receiving element 65, the incoming direction of the spatial optical signal can be estimated. That is, the control circuit 672 selecting the light receiving element 65 corresponds to identifying the communication device as the transmission source of the spatial optical signal. Allocating the signal from the light receiving element 65 selected by the control circuit 672 to any one of the plurality of second processing circuits corresponds to associating the identified communication target with the light receiving element 65 that receives the spatial optical signal from the communication target. That is, the control circuit 672 can identify the communication device as the transmission source of the optical signal (spatial optical signal) based on the optical signal received by each of the plurality of light receiving elements 65-1 to M.

The signal amplified by the amplifier included in each of the plurality of first processing circuits 671-1 to M is input to the selector 673. The selector 673 outputs a signal to be received among the input signals to any one of the plurality of second processing circuits 675-1 to N under the control of the control circuit 672. A signal that is not to be received is not output from the selector 673.

A signal from any one of the plurality of light receiving elements 65-1 to N allocated by the control circuit 672 is input to any of the plurality of second processing circuits 675-1 to N. Each of the plurality of second processing circuits 675-1 to N decodes the input signal. Each of the plurality of second processing circuits 675-1 to N may be configured to perform some signal process on the decoded signal, or may be configured to output the signal to an external signal processing device or the like (not illustrated).

When the selector 673 selects a signal derived from the light receiving element 65 selected by the control circuit 672, one second processing circuit 675 is allocated to one communication target. That is, the control circuit 672 allocates the signals derived from the spatial optical signal from the plurality of communication targets received by the plurality of light receiving elements 65-1 to M to any of the plurality of second processing circuits 675-1 to N. As a result, the reception device 6 can simultaneously read signals derived from spatial optical signals from a plurality of communication targets on individual channels. For example, in order to simultaneously communicate with a plurality of communication targets, the spatial optical signal from the plurality of communication targets may be read in time division on a single channel. In the method of the present example embodiment, since the spatial optical signal from a plurality of communication targets is simultaneously read in a plurality of channels, a transmission speed is faster than that in a case where a single channel is used.

For example, a configuration may be employed in which the incoming direction of the spatial optical signal is identified by the primary scan with coarse accuracy, and the secondary scan with fine accuracy is performed with respect to the identified direction to identify the accurate position of the communication target. When communication with the communication target is possible, an accurate position of the communication target can be determined by exchanging signals with the communication target. When the position of the communication target is identified in advance, the process of identifying the position of the communication target can be omitted.

As described above, the reception device according to the present example embodiment includes the ball lens, the light guide, the plurality of light receiving elements, and the reception circuit. The ball lens collects the optical signal propagating in the space. The light guide includes a plurality of base-units annularly disposed around the ball lens. The light guide guides the optical signal collected by the ball lens in a direction substantially perpendicular to the incidence direction of the optical signal. The plurality of light receiving elements is associated with the plurality of respective base-units. The light receiving element receives an optical signal emitted from the base-unit. The light receiving element outputs a signal derived from the received optical signal. The transmission device transmits a spatial optical signal. The reception circuit acquires signals output from the plurality of light receiving elements. The reception circuit decodes the acquired signal.

The reception device according to the present example embodiment guides an optical signal coming from various directions toward a light receiving element associated with any one of a plurality of base-units constituting a light guide. The reception device of the present example embodiment decodes the optical signal received by the light receiving element. According to the reception device of the present example embodiment, the optical signal coming from various directions can be collectively decoded for each base-unit constituting the light guide. Therefore, according to the reception device of the present example embodiment, the optical signal coming from various directions can be decoded.

### Seventh Example Embodiment

Next, a communication device according to a seventh example embodiment will be described with reference to the drawings. The communication device according to the present example embodiment includes the reception device according to any one of the first to sixth example embodiments and the transmission device that transmits a spatial optical signal according to a received spatial optical signal. Hereinafter, an example of a communication device including a transmission device including a phase modulation type spatial light modulator will be described. The communication device of the present example embodiment may include a transmission device including a light transmission function that is not a phase modulation type spatial light modulator.

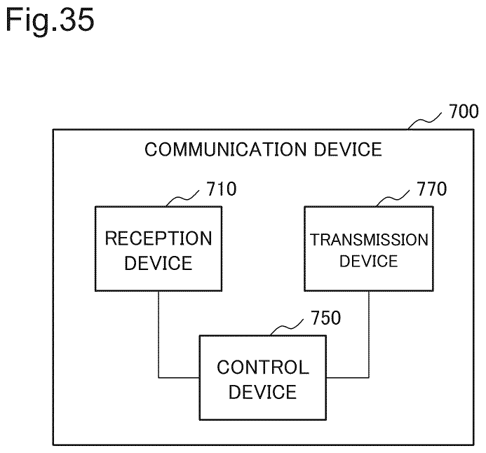

FIG. 35 is a conceptual diagram illustrating an example of a configuration of the communication device 700-1 of the present example embodiment. The communication device 700-1 includes a reception device 710, a control device 750, and a transmission device 770. The reception device 710 and the transmission device 770 transmit and receive a spatial optical signal to and from an external communication target. Therefore, the communication device 700-1 has an opening or a window for transmitting and receiving a spatial optical signal.

The reception device 710 is a reception device according to any one of the first to sixth example embodiments. The reception device 710 may be a reception device having a configuration in which the first to sixth example embodiments are combined. The reception device 710 receives a spatial optical signal transmitted from a communication target (not illustrated). The reception device 710 converts the received spatial optical signal into an electric signal. The reception device 710 outputs the converted electric signal to the control device 750.

The control device 750 acquires a signal output from the reception device 710. The control device 750 performs a process according to the acquired signal. The process performed by the control device 750 is not particularly limited. The control device 750 outputs a control signal for transmitting an optical signal related to the performed process to the transmission device 770. For example, the control device 750 performs a process based on a predetermined condition according to information included in the signal received by the reception device 710. For example, the control device 750 executes processing related to an operation input by the user according to information included in a signal received by the reception device 710.

The transmission device 770 acquires a control signal from the control device 750. The transmission device 770 projects a spatial optical signal according to the control signal. The spatial optical signal projected from the transmission device 770 is received by a communication target (not illustrated). For example, the transmission device 770 includes a phase modulation type spatial light modulator. The transmission device 770 may include a light transmission function that is not a phase modulation type spatial light modulator.

### [Transmission Device]

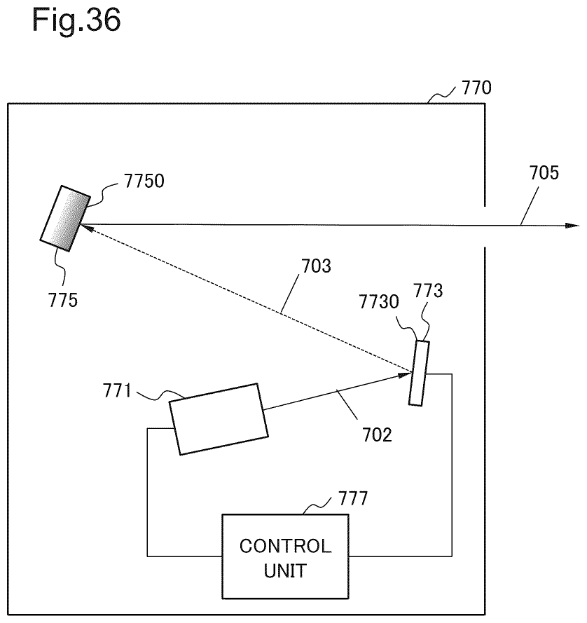

FIG. 36 is a conceptual diagram illustrating an example of a configuration of the transmission device 770. The transmission device 770 includes a light source 771, a spatial light modulator 773, a curved face mirror 775, and a control unit 777. FIG. 36 is a side view of the internal configuration of the transmission device 770 when viewed from the side. FIG. 36 is conceptual, and does not accurately represent the positional relationship between the components, the traveling direction of light, and the like.

The light source 771 emits laser light in a predetermined wavelength band under the control of the control unit 777. The wavelength of the laser light emitted from the light source 771 is not particularly limited, and may be selected according to the application. For example, the light source 771 emits laser light in visible or infrared wavelength bands. For example, in the case of near infrared rays of 800 to 900 nanometers (nm), the laser class can be increased, so that the sensitivity can be improved by about one digit as compared with other wavelength bands. For example, a high-output laser beam source can be used for infrared rays in a wavelength band of 1.55 micrometers (μm). As an infrared laser beam source in a wavelength band of 1.55 μm, an aluminum gallium arsenide phosphorus (AlGaAsP)-based laser beam source, an indium gallium arsenide (InGaAs)-based laser beam source, or the like can be used. The longer the wavelength of the laser light is, the larger the diffraction angle can be made and the higher the energy can be set. The light source 771 includes a lens that enlarges the laser light in accordance with the size of the modulation region set in a modulation part 7730 of the spatial light modulator 773. The light source 771 emits light 702 enlarged by the lens. The light 702 emitted from the light source 771 travels toward the modulation part 7730 of the spatial light modulator 773.

The spatial light modulator 773 includes modulation part 7730 irradiated with the light 702. The modulation part 7730 of the spatial light modulator 773 is irradiated with the light 702 emitted from the light source 771. A modulation region is set in the modulation part 7730 of the spatial light modulator 773. In the modulation region of modulation part 7730, a pattern (also referred to as a phase image) related to the image displayed by projection light 705 is set according to the control of the control unit 777. The light 702 incident on the modulation part 7730 of the spatial light modulator 773 is modulated according to the pattern set in the modulation part 7730 of the spatial light modulator 773. Modulated light 703 modulated by modulation part 7730 of spatial light modulator 773 travels toward a reflection face 7750 of the curved face mirror 775.

For example, the spatial light modulator 773 is achieved by a spatial light modulator using ferroelectric liquid crystal, homogeneous liquid crystal, vertical alignment liquid crystal, or the like. For example, the spatial light modulator 773 can be achieved by liquid crystal on silicon (LCOS). The spatial light modulator 773 may be achieved by a micro electro mechanical system (MEMS). In the phase modulation type spatial light modulator 773, the energy can be concentrated on the portion of the image by operating to sequentially switch the portion on which the projection light 705 is projected. Therefore, in the case of using the phase modulation type spatial light modulator 773, when the output of the light source 771 is the same, the image can be displayed brighter than that of other methods.

The modulation region of the modulation part 7730 of the spatial light modulator 773 is divided into a plurality of regions (also referred to as tiling). For example, the modulation region of the modulation part 7730 is divided into rectangular regions (also referred to as tiles) having a desired aspect ratio. A phase image is allocated to each of the plurality of tiles set in the modulation region of the modulation part 7730. Each of the plurality of tiles includes a plurality of pixels. A phase image related to a projected image is set to each of the plurality of tiles. The phase images set to the plurality of tiles may be the same or different.

A phase image is tiled to each of the plurality of tiles allocated to the modulation region of the modulation part 7730. For example, a phase image generated in advance is set in each of the plurality of tiles. When the modulation part 7730 is irradiated with the light 702 in a state where the phase images are set for the plurality of tiles, the modulated light 703 that forms an image related to the phase image of each tile is emitted. As the number of tiles set in the modulation part 7730 increases, a clear image can be displayed. However, when the number of pixels of each tile decreases, the resolution decreases. Therefore, the size and the number of tiles set in the modulation region of the modulation part 7730 are set according to the application.

The curved face mirror 775 is a reflecting mirror having the curved reflection face 7750. The reflection face 7750 of the curved face mirror 775 has a curvature related to the projection angle of the projection light 705. The reflection face 7750 of the curved face mirror 775 may be a curved face. In the example of FIG. 36, the reflection face 7750 of the curved face mirror 775 has a shape of a side face of a cylinder. For example, the reflection face 7750 of the curved face mirror 775 may be a spherical face. For example, the reflection face 7750 of the curved face mirror 775 may be a free-form surface. For example, the reflection face 7750 of the curved face mirror 775 may have a shape in which a plurality of curved faces is combined instead of a single curved face. For example, the reflection face 7750 of the curved face mirror 775 may have a shape in which a curved face and a flat face are combined.

The curved face mirror 775 is disposed on an optical path of the modulated light 703 with the reflection face 7750 facing the modulation part 7730 of the spatial light modulator 773. The reflection face 7750 of the curved face mirror 775 is irradiated with the modulated light 703 modulated by the modulation part 7730 of the spatial light modulator 773. The light (projection light 705) reflected by the reflection face 7750 of the curved face mirror 775 is enlarged and projected at an enlargement ratio in accordance with the curvature of the reflection face 7750. In the case of the example of FIG. 33, the projection light 705 is enlarged along the horizontal direction (the direction perpendicular to the paper surface of FIG. 36) according to the curvature of the radiation range of modulated light 703 on reflection face 7750 of the curved face mirror 775.

For example, a shielder (not illustrated) may be disposed between the spatial light modulator 773 and the curved face mirror 775. In other words, the shielder may be disposed on an optical path of the modulated light 703 modulated by the modulation part 7730 of the spatial light modulator 773. The shielder is a frame that shields unnecessary light components included in the modulated light 703 and defines an outer edge of a display region of the projection light 705. For example, the shielder is an aperture in which a slit-shaped opening is formed in a portion through which light forming a desired image passes. The shielder transmits light that forms a desired image and shields unwanted light components. For example, the shielder shields 0th-order light or a ghost image included in the modulated light 703. Details of the shielder will not be described.

Although curved face mirror 775 is used in the example of FIG. 36, transmission device 770 may be provided with a projection optical system including a Fourier transform lens, a projection lens, and the like instead of the curved face mirror 775. The transmission device 770 may be configured to directly project the light modulated by the modulation part 7730 of the spatial light modulator 773 without using the curved face mirror 775 or the projection optical system.

The control unit 777 controls the light source 771 and the spatial light modulator 773. For example, the control unit 777 is achieved by a microcomputer including a processor and a memory. The control unit 777 sets a phase image related to the projected image in the modulation part 7730 in accordance with the aspect ratio of tiling set in the modulation part 7730 of the spatial light modulator 773. For example, the control unit 777 sets, in the modulation part 7730, a phase image related to an image according to a use such as an image display, communication, or distance measurement. The phase image of the projected image may be stored in advance in a storage unit (not illustrated). The shape and the size of the image to be projected are not particularly limited.

The control unit 777 drives the spatial light modulator 773 in such a way that a parameter that determines a difference between a phase of the light 702 with which the modulation part 7730 of the spatial light modulator 773 is irradiated and a phase of the modulated light 703 reflected by the modulation part 7730 changes. For example, the parameter is a value related to optical characteristics such as a refractive index and an optical path length. For example, the control unit 777 adjusts the refractive index of the modulation part 7730 by changing the voltage applied to the modulation part 7730 of the spatial light modulator 773. The phase distribution of the light 702 with which the modulation part 7730 of the phase modulation type spatial light modulator 773 is irradiated is modulated according to the optical characteristics of the modulation part 7730. The method of driving the spatial light modulator 773 by the control unit 777 is determined according to the modulation scheme of the spatial light modulator 773.

The control unit 777 drives the light source 771 in a state where the phase image related to the image to be displayed is set in the modulation part 7730. As a result, the modulation part 7730 of the spatial light modulator 773 is irradiated with the light 702 emitted from the light source 771 in accordance with the timing at which the phase image is set in the modulation part 7730 of the spatial light modulator 773. The light 702 with which the modulation part 7730 of the spatial light modulator 773 is irradiated is modulated by the modulation part 7730 of the spatial light modulator 773. The modulated light 703 modulated by the modulation part 7730 of the spatial light modulator 773 is emitted toward the reflection face 7750 of the curved face mirror 775.

For example, the curvature of the reflection face 7750 of the curved face mirror 775 included in the transmission device 770 and the distance between the spatial light modulator 773 and the curved face mirror 775 are adjusted, and the projection angle of the projection light 705 is set to 180 degrees. By using two transmission devices 770 configured as described above, the projection angle of projection light 705 can be set to 360 degrees. When part of the modulated light 703 is folded back with a plane mirror or the like inside the transmission device 770, and the projection light 705 is projected in two directions, the projection angle of the projection light 705 can be set to 360 degrees. For example, the transmission device 770 configured to project projection light in a direction of 360 degrees and the reception device 2 of the second example embodiment are combined. With such a configuration, it is possible to achieve a communication device that transmits a spatial optical signal in a direction of 360 degrees and receives a spatial optical signal coming from a direction of 360 degrees.

### [Communication Device]

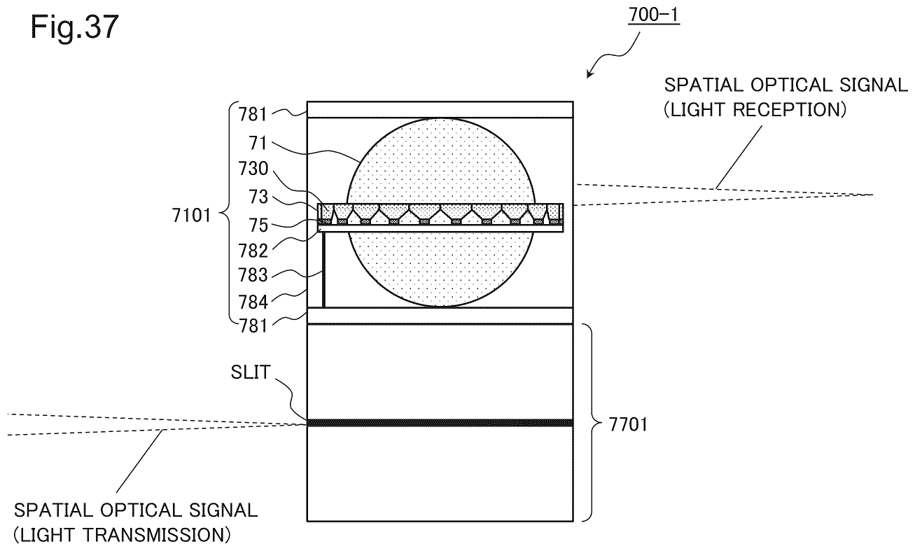

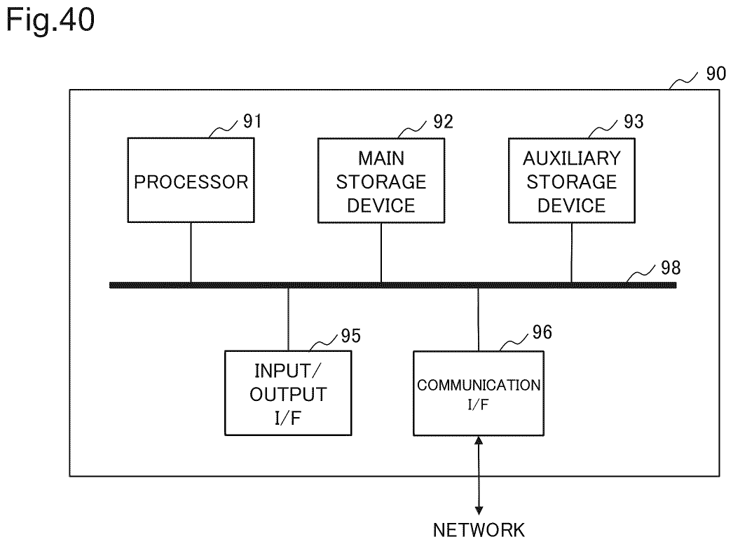

FIG. 37 is a conceptual diagram illustrating an example of a configuration of a communication device 700-1. The communication device 700-1 includes a receiver 7101, a transmitter 7701, and a control device (not illustrated). In FIG. 40, the reception circuit and the control device are omitted. The communication device 700-1 has a configuration in which a receiver 7101 having the cylindrical outer shape and the transmitter 7701 are combined.

The receiver 7101 includes a ball lens 71, a light guide 73, a plurality of light receiving elements 75, a support element 781, a substrate 782, a conductive wire 783, and a color filter 784. The upper and lower portions of the ball lens 71 are sandwiched by a pair of support elements 781 disposed at the upper side and the lower side. Since the upper and lower parts of the ball lens 71 are not used for transmission and reception of a spatial optical signal, they may be processed into a planar shape in such a way as to be easily sandwiched by the support element 781. The light guide 73 is disposed in accordance with the condensing region of the ball lens 71 in such a way as to be able to receive the spatial optical signal to be received. The light guide 73 includes a plurality of base-units 730. The light receiving element 75 is associated with each of the plurality of base-units 730. The plurality of light receiving elements 75 is disposed on the substrate 782. Each of the plurality of light receiving elements 75 is connected to a control device (not illustrated) or the transmitter 7701 by the conductive wire 783.

The color filter 784 is disposed on the side face of the cylindrical receiver 7101. The color filter 784 removes unnecessary light and selectively transmits a spatial optical signal used for communication. A pair of support elements 781 is disposed on upper and lower faces of the cylindrical receiver 7101. The pair of support elements 781 sandwiches the upper and lower parts of the ball lens 71. The light guide 73 formed in an annular shape is disposed on the emission side of the ball lens 71. The spatial optical signal incident on the ball lens 71 through the color filter 784 is collected toward the light guide 73 by the ball lens 71. The optical signal collected by the light guide 73 is guided by any of the base-units 730 toward the light receiving unit of the light receiving element 75 associated with the base-unit 730. The optical signal reaching the light receiving unit of the light receiving element 75 is received by the light receiving element 75. The control device (not illustrated) causes the transmitter 7701 to transmit a spatial optical signal according to the optical signal received by the light guide 73.

The transmitter 7701 can be implemented by the configuration in FIG. 36. The transmitter 7701 is housed inside a cylindrical housing. A slit opened in accordance with the transmission direction of the spatial optical signal by the transmitter 7701 is formed in the cylindrical housing. For example, in a case where the transmitter 7701 can transmit the spatial optical signal in the direction of 360 degrees, a slit that goes around the side face is formed in the housing of the transmitter 7701 in accordance with the transmission direction of the spatial optical signal.

### Application Example 1

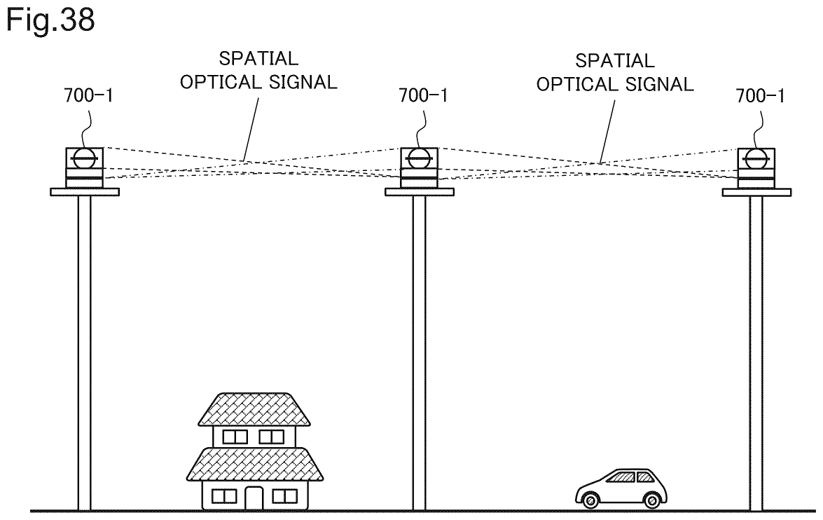

Next, the application example 1 of the communication device 700-1 according to the present example embodiment will be described with reference to the drawings. FIG. 38 is a conceptual diagram for describing the present application example. In the present application example, an example of a communication network (also referred to as a communication system) in which a plurality of communication devices 700-1 is disposed on an upper portion (also referred to as a space above the pillar) of a pillar such as a utility pole or a street lamp will be described.

There are few obstacles on an upper portion (space above the pillar) of a pole such as a utility pole or a street lamp. Therefore, the space above the pillar is suitable for installing the communication device 700-1. When the communication device 700-1 is installed at the same height, the incoming direction of the spatial optical signal is limited to the horizontal direction, so that the light receiving area of the light guide 73 constituting the receiver 7101 can be reduced and the device can be simplified. The pair of communication devices 700-1 that transmit and receive the spatial optical signal is disposed in such a way that at least one communication device 700-1 receives the spatial optical signal transmitted from the other communication device 700-1. The pair of communication devices 700-1 may be disposed to transmit and receive the spatial optical signal to and from each other. In a case where the communication network of the spatial optical signal is configured by the plurality of communication devices 700-1, the communication device 700-1 positioned in the middle may be disposed to relay the spatial optical signal transmitted from other communication device 700-1 to another communication device 700-1.

According to the present application example, communication using a spatial optical signal is possible among the plurality of communication devices 700-1 disposed in the space above the pillar. For example, it may be configured in such a way that communication by wireless communication is performed between a wireless device installed in an automobile, a house, or the like, or a base station and the communication device 700-1 according to communication between the communication devices 700-1 each disposed in the space above the pillar. For example, the communication device 700-1 may be configured to be connected to the Internet via a communication cable or the like installed on a pillar.

As described above, the communication device according to the present example embodiment includes a reception device, a transmission device, and a control device. The reception device includes a ball lens, a light guide, a plurality of light receiving elements, and a reception circuit. The ball lens collects the optical signal propagating in the space. The light guide includes a plurality of base-units annularly disposed around the ball lens. The light guide guides the optical signal collected by the ball lens in a direction substantially perpendicular to the incidence direction of the optical signal. The plurality of light receiving elements is associated with the plurality of respective base-units. The light receiving element receives an optical signal emitted from the base-unit. The light receiving element outputs a signal derived from the received optical signal. The transmission device transmits a spatial optical signal. The reception circuit acquires signals output from the plurality of light receiving elements. The reception circuit decodes the acquired signal. The control device acquires a signal based on a spatial optical signal, from other communication device, received by the reception device. The control device performs a process according to the acquired signal. The control device causes the transmission device to transmit a spatial optical signal related to the performed processing.

The communication device according to the present example embodiment includes a reception device that guides an optical signal coming from various directions toward a light receiving element associated with any of a plurality of base-units constituting a light guide. According to the communication device of the present example embodiment, since the optical signal coming from various directions can be collectively received for each base-unit constituting the light guide, the number of light receiving elements can be reduced. Therefore, according to the communication device of the present example embodiment, the optical signal coming from various directions can be received using an appropriate number of light receiving elements.

A communication system according to an aspect of the present example embodiment includes a plurality of the above-described communication device. In a communication system, a plurality of communication devices is disposed to transmit and receive the spatial optical signal to and from each other. According to the present aspect, it is possible to achieve a communication network that transmits and receives a spatial optical signal.

### Eighth Example Embodiment

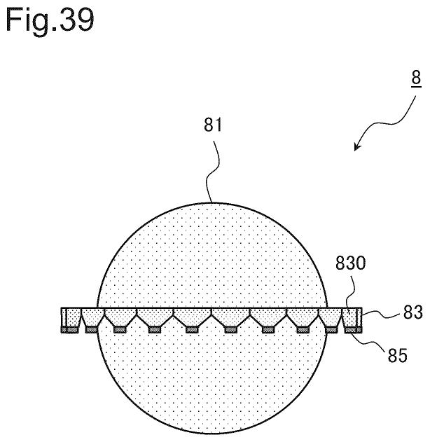

Next, the reception device according to an eighth example embodiment will be described with reference to the drawings. The reception device of the present example embodiment has a configuration in which the reception device of each of the first to sixth example embodiments is simplified. FIG. 39 is a conceptual diagram illustrating an example of a configuration of a reception device 8 according to the present example embodiment. The reception device 8 includes a ball lens 81, a light guide 83, and a plurality of light receiving elements 85.

The ball lens 81 collects the optical signal propagating in the space. The light guide 83 includes a plurality of base-units 830 annularly disposed around the ball lens 81. The light guide 83 guides the optical signal collected by the ball lens 81 in a direction substantially perpendicular to the incidence direction of the optical signal. The plurality of light receiving elements 85 is associated with the plurality of respective base-units 830. The light receiving element 85 receives the optical signal emitted from the base-unit 830. The light receiving element 85 outputs a signal derived from the received optical signal.

As described above, the reception device of the present example embodiment guides the optical signal coming from various directions toward the light receiving element associated with the base-unit by any of the plurality of base-units constituting the light guide. According to the reception device of the present example embodiment, since the optical signal coming from various directions can be collectively received by each base-unit constituting the light guide, the number of light receiving elements can be reduced. Therefore, according to the reception device of the present example embodiment, the optical signal coming from various directions can be received using an appropriate number of light receiving elements.

### (Hardware)

A hardware configuration for executing control and processing according to each example embodiment of the present disclosure will be described using an information processing device 90 of FIG. 40 as an example. The information processing device 90 in FIG. 40 is a configuration example for performing control and a process of each example embodiment, and does not limit the scope of the present disclosure.

As illustrated in FIG. 40, the information processing device 90 includes a processor 91, a main storage device 92, an auxiliary storage device 93, an input/output interface 95, and a communication interface 96. In FIG. 40, the interface is abbreviated as an interface (I/F). The processor 91, the main storage device 92, the auxiliary storage device 93, the input/output interface 95, and the communication interface 96 are data-communicably connected to each other via a bus 98. The processor 91, the main storage device 92, the auxiliary storage device 93, and the input/output interface 95 are connected to a network such as the Internet or an intranet via the communication interface 96.

The processor 91 develops the program stored in the auxiliary storage device 93 or the like in the main storage device 92. The processor 91 executes the program developed in the main storage device 92. In the present example embodiment, a software program installed in the information processing device 90 may be used. The processor 91 executes control and processing according to each example embodiment.

The main storage device 92 has an area in which a program is developed. A program stored in the auxiliary storage device 93 or the like is developed in the main storage device 92 by the processor 91. The main storage device 92 is achieved by, for example, a volatile memory such as a dynamic random access memory (DRAM). A nonvolatile memory such as a magnetoresistive random access memory (MRAM) may be configured and added as the main storage device 92.

The auxiliary storage device 93 stores various pieces of data such as programs. The auxiliary storage device 93 is achieved by a local disk such as a hard disk or a flash memory. Various pieces of data may be stored in the main storage device 92, and the auxiliary storage device 93 may be omitted.

The input/output interface 95 is an interface that connects the information processing device 90 with a peripheral device based on a standard or a specification. The communication interface 96 is an interface that connects to an external system or a device through a network such as the Internet or an intranet in accordance with a standard or a specification. The input/output interface 95 and the communication interface 96 may be shared as an interface connected to an external device.

An input device such as a keyboard, a mouse, or a touch panel may be connected to the information processing device 90 as necessary. These input devices are used to input of information and settings. In a case where the touch panel is used as the input device, the display screen of the display device may also serve as the interface of the input device. Data communication between the processor 91 and the input device may be mediated by the input/output interface 95.

The information processing device 90 may be provided with a display device that displays information. In a case where a display device is provided, the information processing device 90 preferably includes a display control device (not illustrated) that controls display of the display device. The display device may be connected to the information processing device 90 via the input/output interface 95.

The information processing device 90 may be provided with a drive device. The drive device mediates reading of data and a program from the recording medium, writing of a processing result of the information processing device 90 to the recording medium, and the like between the processor 91 and the recording medium (program recording medium). The drive device may be connected to the information processing device 90 via the input/output interface 95.

The above is an example of a hardware configuration for enabling control and processing according to each example embodiment of the present invention. The hardware configuration of FIG. 40 is an example of a hardware configuration for executing control and processing according to each example embodiment, and does not limit the scope of the present invention. A program for causing a computer to execute control and processing according to each example embodiment is also included in the scope of the present invention. A program recording medium in which the program according to each example embodiment is recorded is also included in the scope of the present invention. The recording medium can be achieved by, for example, an optical recording medium such as a compact disc (CD) or a digital versatile disc (DVD). The recording medium may be achieved by a semiconductor recording medium such as a Universal Serial Bus (USB) memory or a secure digital (SD) card. The recording medium may be achieved by a magnetic recording medium such as a flexible disk, or another recording medium. In a case where the program executed by the processor is recorded in the recording medium, the recording medium corresponds to a program recording medium.

The components of each example embodiment may be combined in any manner. The components of each example embodiment may be achieved by software or may be achieved by a circuit.

While the present invention is described with reference to example embodiments thereof, the present invention is not limited to these example embodiments. Various modifications that can be understood by those of ordinary skill in the art can be made to the configuration and details of the present invention within the scope of the present invention.

Some or all of the above example embodiments may be described as the following Supplementary Notes, but are not limited to the following.

### (Supplementary Note 1)

A reception device including
a ball lens that collects an optical signal propagating through a space,
a light guide including a plurality of base-units annularly disposed around the ball lens, the light guide guiding the optical signal collected by the ball lens in a direction substantially perpendicular to an incidence direction of the optical signal, and
a plurality of light receiving elements respectively related to the plurality of base-units, the light receiving elements receiving the optical signal emitted from the base-units and outputting a signal derived from the received optical signal.

### (Supplementary Note 2)

The reception device according to Supplementary Note 1, wherein
the base-unit includes
a light guide body including a first face including an incident face on which the optical signal collected by the ball lens is incident, a second face facing the first face, and an emission end from which the optical signal incident on the incident face is emitted, and
a light traveling direction changing element that is disposed at a position close to the second face, the position facing the incident face, and changes a traveling direction of the optical signal incident on the incident face toward the emission end, and wherein
the light receiving element
is disposed with a light receiving unit that receives light in a wavelength region of the optical signal facing the emission end of the base-unit.

### (Supplementary Note 3)

The reception device according to Supplementary Note 2, wherein
the light traveling direction changing element includes
a diffraction element that is disposed at a position facing the incident face on the second face side, and diffracts the optical signal incident on the incident face toward the emission end.

### (Supplementary Note 4)

The reception device according to Supplementary Note 2, wherein
the light traveling direction changing element includes
a multi-mirror in which a plurality of reflection faces that is disposed at a position facing the incident face on the second face side, and reflects the optical signal incident on the incident face toward the emission end is combined.

### (Supplementary Note 5)

The reception device according to any one of Supplementary Notes 2 to 4, wherein
the base-unit
is disposed in such a way as to guide the optical signal incident on the incident face in a direction perpendicular to a face formed by an array of the plurality of base-units.

### (Supplementary Note 6)

The reception device according to any one of Supplementary Notes 2 to 4, wherein
the base-unit
is disposed in such a way as to guide the optical signal incident on the incident face in a direction along a circumferential direction of a circle formed by an array of the plurality of base-units, and wherein
the emission end of each of the base-units
is disposed close to the second face of an adjacent base-unit.

### (Supplementary Note 7)

The reception device according to Supplementary Note 1, wherein
the base-unit includes
a concave curved face including an incident face that reflects the optical signal, a convex curved face facing the concave curved face, and an emission end to which the optical signal incident on the incident face is guided, wherein
the plurality of base-units
is disposed with the concave curved face facing the ball lens in such a way as to guide the optical signal incident on the incident face in a direction along a circumferential direction of a circle formed by an array of the plurality of base-units, wherein
the emission end of each of the base-units
is disposed close to the convex curved face of an adjacent base-unit, and wherein
the light receiving element
includes a light receiving unit that receives light in a wavelength region of the optical signal, is disposed with the light receiving unit facing the emission end of the base-unit, and receives the optical signal reflected and guided by the concave curved face of an associated base-unit and the convex curved face of a base-unit adjacent to the associated base-unit.

### (Supplementary Note 8)

The reception device according to Supplementary Note 1, wherein
the base-unit includes
a first curved face mirror including an incident face that reflects the optical signal, and a second curved face mirror with a reflection face facing the first curved face mirror, wherein
the plurality of the first curved face mirrors
is disposed with the incident face facing the ball lens, and wherein
the light receiving element
includes a light receiving unit that receives light in a wavelength region of the optical signal and is disposed on a curved face same as the incident face of the first curved face mirror of an associated base-unit with the light receiving unit facing the reflection face of the second curved face mirror.

### (Supplementary Note 9)

The reception device according to Supplementary Note 1, wherein
the base-unit includes
a first curved face mirror including an incident face that reflects the optical signal, wherein
the plurality of the first curved face mirrors
is disposed with the incident face facing the ball lens, and wherein
the light receiving element
is disposed with a light receiving unit that receives light in a wavelength region of the optical signal facing the incident face of the first curved face mirror of an associated base-unit.

### (Supplementary Note 10)

The reception device according to any one of Supplementary Notes 1 to 9, further including a light guide auxiliary device that is disposed between the ball lens and the light guide and guides the optical signal collected by the ball lens toward the light guide.

### (Supplementary Note 11)

The reception device according to Supplementary Note 10, wherein
the light guide auxiliary device includes
a plurality of shielding layers disposed along a diameter direction of the ball lens and
a plurality of transparent layers that is formed between the plurality of shielding layers and through which the optical signal is transmitted.

### (Supplementary Note 12)

The reception device according to Supplementary Note 10, wherein
the light guide auxiliary device includes
a plurality of partition walls disposed along a diameter direction of the ball lens.

### (Supplementary Note 13)

The reception device according to any one of Supplementary Notes 10 to 12, wherein
the light guide auxiliary device
is disposed in close contact with the ball lens.

### (Supplementary Note 14)

A reception device including according to any one of Supplementary Notes 1 to 13, further including a reception circuit that acquires the signal output from the plurality of light receiving elements and decodes the acquired signal.

### (Supplementary Note 15)

A communication device including
the reception device according to Supplementary Note 14,
a transmission device that transmits a spatial optical signal, and
a control device that acquires a signal based on a spatial optical signal, from other communication device, received by the reception device, performs a process according to the acquired signal, and causes the transmission device to transmit a spatial optical signal according to the performed process.

### (Supplementary Note 16)

A communication system including
a plurality of the communication devices according to Supplementary Note 15, wherein
the plurality of communication devices
is disposed in such a way as to transmit and receive a spatial optical signal to and from each other.

### REFERENCE SIGNS LIST

1, 2, 3, 4, 5, 6 reception device
11, 21, 31, 41, 51, 61 ball lens
13, 23, 33, 43, 53, 63 light guide
15, 25, 35, 45, 65 light receiving element
46 light shielding band
57 light guide auxiliary device
60 light receiving unit
67 reception circuit
130, 230, 330, 430 base-unit
133, 233 light guide body
135 diffraction element
235 multi-mirror
431 first curved face mirror
432 second curved face mirror
571 transparent layer
572 shielding layer
575 partition wall
671 first processing circuit
672 control circuit
673 selector
675 second processing circuit
700 communication device
710 reception device
750 control device
770 transmission device
771 light source
773 spatial light modulator
775 curved face mirror
781 support element
782 substrate
783 conductive wire
784 color filter
7101 receiver
7701 transmitter

What is claimed is:

1. A reception device comprising:
a ball lens that collects an optical signal propagating through a space;
a light guide including a plurality of base-units annularly disposed around the ball lens, the light guide guiding the optical signal collected by the ball lens in a direction substantially perpendicular to an incidence direction of the optical signal; and
a plurality of light receiving elements respectively related to the plurality of base-units, the light receiving elements receiving the optical signal emitted from the base-units and outputting a signal derived from the received optical signal.

2. The reception device according to claim 1, wherein
the base-unit includes
a light guide body including a first face including an incident face on which the optical signal collected by the ball lens is incident, a second face facing the first face, and an emission end from which the optical signal incident on the incident face is emitted, and
a light traveling direction changing element that is disposed at a position close to the second face, the position facing the incident face, and changes a traveling direction of the optical signal incident on the incident face toward the emission end, and wherein
the light receiving element
is disposed with a light receiving unit that receives light in a wavelength region of the optical signal facing the emission end of the base-unit.

3. The reception device according to claim 2, wherein
the light traveling direction changing element includes
a diffraction element that diffracts the optical signal incident on the incident face toward the emission end.

4. The reception device according to claim 2, wherein
the light traveling direction changing element includes
a multi-mirror in which a plurality of reflection faces that reflect the optical signal incident on the incident face toward the emission end is combined.

5. The reception device according to claim 2, wherein
the base-unit
is disposed in such a way as to guide the optical signal incident on the incident face in a direction perpendicular to a face formed by an array of the plurality of base-units.

6. The reception device according to claim 2, wherein
the base-unit
is disposed in such a way as to guide the optical signal incident on the incident face in a direction along a circumferential direction of a circle formed by an array of the plurality of base-units, and wherein
the emission end of each of the base-units
is disposed close to the second face of an adjacent base-unit.

7. The reception device according to claim 1, wherein
the base-unit includes
a concave curved face including an incident face that reflects the optical signal, a convex curved face facing the concave curved face, and an emission end to which the optical signal incident on the incident face is guided, wherein
the plurality of base-units
is disposed with the concave curved face facing the ball lens in such a way as to guide the optical signal incident on the incident face in a direction along a circumferential direction of a circle formed by an array of the plurality of base-units, wherein
the emission end of each of the base-units
is disposed close to the convex curved face of an adjacent base-unit, and wherein
the light receiving element
includes a light receiving unit that receives light in a wavelength region of the optical signal, is disposed with the light receiving unit facing the emission end of the base-unit, and receives the optical signal reflected and guided by the concave curved face of an associated base-unit and the convex curved face of a base-unit adjacent to the associated base-unit.

8. The reception device according to claim 1, wherein
the base-unit includes
a first curved face mirror including an incident face that reflects the optical signal, and a second curved face mirror with a reflection face facing the first curved face mirror, wherein
the plurality of the first curved face mirrors
is disposed with the incident face facing the ball lens, and wherein
the light receiving element
is disposed on a curved face same as the incident face of the first curved face mirror of an associated base-unit with a light receiving unit that receives light in a wavelength region of the optical signal facing the reflection face of the second curved face mirror.

9. The reception device according to claim 1, wherein
the base-unit includes
a first curved face mirror including an incident face that reflects the optical signal, wherein
the plurality of the first curved face mirrors
is disposed with the incident face facing the ball lens, and wherein
the light receiving element
is disposed with a light receiving unit that receives light in a wavelength region of the optical signal facing the incident face of the first curved face mirror of an associated base-unit.

10. The reception device according to claim 1, further comprising
a light guide auxiliary device that is disposed between the ball lens and the light guide, and guides the optical signal collected by the ball lens toward the light guide.

11. The reception device according to claim 10, wherein
the light guide auxiliary device includes
a plurality of shielding layers disposed along a diameter direction of the ball lens, and
a plurality of transparent layers that is formed between the plurality of shielding layers and through which the optical signal is transmitted.

12. The reception device according to claim 10, wherein
the light guide auxiliary device includes
a plurality of partition walls disposed along a diameter direction of the ball lens.

13. The reception device according to claim 1, wherein
the light guide auxiliary device
is disposed in close contact with the ball lens.

14. A reception device comprising according to claim 1, further comprising
a receiver that acquires the signal output from the plurality of light receiving elements and decodes the acquired signal.

15. A communication device comprising:
the reception device according to claim 14;
a transmission device that transmits a spatial optical signal; and
a control device that comprises a memory storing instructions, and a processor connected to the memory and is-configured to execute the instructions to acquire a signal based on a spatial optical signal, from other communication device, received by the reception device, perform a process according to the acquired signal, and cause the transmission device to transmit a spatial optical signal according to the performed process.

16. A communication system comprising:
a plurality of the communication devices according to claim 15, wherein
the plurality of communication devices
is disposed in such a way as to transmit and receive a spatial optical signal to and from each other.
